(19) United States
(12) Patent Application Publication
(10) Pub. No.: US 2016/0339678 A1
(43) Pub. Date: Nov. 24, 2016

(54) CYCLIC OLEFIN-BASED FILM, OPTICAL FILM, CONDUCTIVE FILM, BASE FILM FOR PRINTED ELECTRONICS, BARRIER FILM, TOUCH PANEL, POLARIZATION PLATE, AND DISPLAY DEVICE

(71) Applicant: FUJIFILM Corporation, Tokyo (JP)

(72) Inventors: Ryuta TAKEGAMI, Fujinomiya-shi (JP); Naomi WATANABE, Fujinomiya-shi (JP)

(73) Assignee: FUJIFILM Corporation, Tokyo (JP)

(21) Appl. No.: 15/229,223

(22) Filed: Aug. 5, 2016

Related U.S. Application Data
(63) Continuation of application No. PCT/JP2015/053988, filed on Feb. 13, 2015.

(30) Foreign Application Priority Data
Feb. 28, 2014 (JP) 2014-039225

(51) Int. Cl. B32B 27/32; H01L 51/00; H05K 1/03; G02F 1/1335; B32B 27/36; B32B 27/40; G02B 5/30; G02B 1/04; H01L 51/52; B32B 27/08

(52) U.S. Cl. CPC B32B 27/325; H01L 51/5253; H01L 51/0096; H05K 1/036; B32B 27/32; B32B 27/08; B32B 27/36; B32B 27/40; G02B 5/3025; G02B 1/04; G02F 1/133502; G02F 1/133528; B32B 2307/202; B32B 2307/42; B32B 2457/202; B32B 2457/20; B32B 2457/208

(57) ABSTRACT

A cyclic olefin-based film includes an undercoat layer on at least one surface of a layer consisting of a cyclic olefin-based resin, in which a content of an oxazoline group-containing polymer included in the undercoat layer is 2 mass % to 15 mass %.

### CROSS-REFERENCE TO RELATED APPLICATIONS

This application is a Continuation of PCT International Application No. PCT/JP2015/053988 filed on Feb. 13, 2015, which claims priority under 35 U.S.C. §119(a) to Japanese Patent Application No. 2014-039225 filed on Feb. 28, 2014. Each of the above application(s) is hereby expressly incorporated by reference, in its entirety, into the present application.

### BACKGROUND OF THE INVENTION

1. Field of the Invention

The present invention relates to a cyclic olefin-based film, an optical film, a conductive film, a base film for printed electronics, a barrier film, a touch panel, a polarization plate, and a display device.

2. Description of the Related Art

Recently, uses of a liquid crystal display device, an organic electroluminescence display device (organic EL display device), a touch panel, or the like are widened. In this device, various resin films are used for a support, a protective film, or the like. Among these, the film formed from the cyclic olefin-based film has high heat resistance, low water absorption, and thus the cyclic olefin-based film can be preferably used, since dimensional stability is excellent, photoelastic coefficient is low, and birefringence can be suppressed to be low.

However, the cyclic olefin-based film is a non-polar film that does not have a polar group or that has extremely scarce polar groups compared with a polyester-based film or the like, and thus there is a problem in that adhesiveness to other members is deteriorated.

Therefore, for example, JP2013-132871A suggests that an urethane resin layer that functions as an easily adhesive layer is provided on the surface of the cyclic olefin-based film, and the cyclic olefin-based film is adhered to other members via the urethane resin layer.

In JP2014-500984A, disclosed is a polarization plate including a polarizer, an adhesive layer, and a transparent base film, in which the polarization plate has a primer layer formed by using a primer composition including an oxazoline crosslinking agent between the adhesive layer and the transparent base film. However, JP2014-500984A does not disclose an example in which a cyclic olefin-based film is used as a transparent base film, and the content of the oxazoline crosslinking agent in the primer composition including the oxazoline crosslinking agent used in the example is as high as 200 mass %. Further, JP2014-500984A discloses that the adhesive force decreases if the primer layer is 100 nm or less. In JP2013-160802A, an optical compensation film is coated with an easily adhesive composition, and the easily adhesive composition contains an oxazoline crosslinking agent. Manufacturing Example 16 of JP2013-160802A discloses an easily adhesive layer formed by using an easily adhesive composition including polyester urethane and oxazoline-containing polymer, but the content of the oxazoline-containing polymer in the easily adhesive layer is higher than 15 mass %. Further, JP2013-160802A discloses that, if the thickness of the easily adhesive layer is 0.1 sufficient adhesiveness between the polarizer and the protective film cannot be obtained.

### SUMMARY OF THE INVENTION

In JP2013-132871A, there is a problem in that adhesiveness in a state in which the coating film is dry (dry adhesiveness) is not sufficient, and the adhesiveness in a humidifying state (wet adhesiveness) is also insufficient.

In examples of JP2014-500984A, an acryl film having a primer layer with a thickness of 400 nm is manufactured by coating the surface of the acryl film with a primer composition containing an oxazoline crosslinking agent, but the adhesiveness between the cyclic olefin-based film and the primer layer (dry adhesiveness and wet adhesiveness) is not considered. In JP2013-160802A, the adhesiveness between the cyclic olefin-based film and the easily adhesive layer (dry adhesiveness and wet adhesiveness) was not reviewed. In the example of JP2013-160802A, since the cyclic olefin-based film is coated with an adhesive composition containing an oxazoline crosslinking agent, but the thickness after drying is 0.5 there is a problem in that coating failure (coating unevenness, blocking of a film roll, rolling wrinkles, and the like) easily occurs.

The invention is conceived in order to solve the problems above, and a problem to be solved is to provide a cyclic olefin-based film having excellent dry adhesiveness and excellent wet adhesiveness. Further, according to the invention, the problem to be solved is to provide an optical film using the cyclic olefin-based film, a conductive film, a base film for printed electronics, a barrier film, a touch panel, a polarization plate, and a display device.

The present inventors have diligently conducted research in order to solve the problems above, and as a result, found that it is possible to provide a cyclic olefin-based film having excellent dry adhesiveness and excellent wet adhesiveness by providing an undercoat layer including an oxazoline group-containing polymer in a certain amount on at least one surface of a layer consisting of a cyclic olefin-based resin, and completed the invention.

Specifically, the invention has the following configurations.

<1> A cyclic olefin-based film comprising: an undercoat layer on at least one surface of a layer consisting of a cyclic olefin-based resin, in which a content of an oxazoline group-containing polymer included in the undercoat layer is 2 mass % to 15 mass %.

<2> The cyclic olefin-based film according to <1>, in which a thickness of the undercoat layer is 20 nm to 400 nm.

<3> The cyclic olefin-based film according to <1> or <2>, in which the oxazoline group-containing polymer is a water soluble oxazoline group-containing polymer.

<4> The cyclic olefin-based film according to any one of <1> to <3>, in which a content of the oxazoline group-containing polymer in the undercoat layer is 3 mass % to 12 mass %.

<5> The cyclic olefin-based film according to any one of <1> to <4>, in which the oxazoline group-containing polymer has an oxazoline group and a polyalkylene oxide chain.

<6> The cyclic olefin-based film according to any one of <1> to <5>, in which the oxazoline group-containing polymer is an acryl polymer having an oxazoline group and a polyalkylene oxide chain.

<7> The cyclic olefin-based film according to any one of <1> to <6>, in which a glass transition temperature of the oxazoline group-containing polymer is 50° C. or greater.

<8> The cyclic olefin-based film according to any one of <1> to <7>, in which the undercoat layer includes at least one resin selected from a polyolefin resin, an acryl resin, a modified silicone resin, a polyester resin, a polyurethane resin, and a styrene butadiene rubber resin.

<9> A method for manufacturing the cyclic olefin-based film according to any one of <1> to <8>, comprising: forming an undercoat layer by coating at least one surface of a layer consisting of a cyclic olefin-based resin with a coating liquid at least including an oxazoline group-containing polymer and a resin and then curing the coating liquid.

<10> An optical film comprising: the cyclic olefin-based film according to any one of <1> to <8>.

<11> A conductive film comprising: the cyclic olefin-based film according to any one of <1> to <8>; and a conductive layer.

<12> A base film for printed electronics comprising: the cyclic olefin-based film according to any one of <1> to <8>.

<13> A barrier film comprising: the cyclic olefin-based film according to any one of <1> to <8>.

<14> A touch panel comprising: the cyclic olefin-based film according to any one of <1> to <8>; or the conductive film according to <11>.

<15> A polarization plate comprising: the cyclic olefin-based film according to any one of <1> to <8>; or the optical film according to <10>.

<16> A display comprising: the cyclic olefin-based film according to any one of <1> to <8>; the optical film according to <10>; and the polarization plate according to <15>.

According to the invention, it is possible to provide a cyclic olefin-based film having excellent dry adhesiveness and excellent wet adhesiveness. Further, according to the invention, it is possible to provide an optical film, a conductive film, a base film for printed electronics, a barrier film, a touch panel, a polarization plate, and a display using the cyclic olefin-based film.

### DESCRIPTION OF THE PREFERRED EMBODIMENTS

Hereinafter, the invention is described in detail. Explanations of components described below are provided with reference to representative embodiments and specific examples, but the invention is not limited to the embodiments. In this specification, the numerical range described by using the expression “to” means a range including numerical values described before and after the expression “to”, as upper and lower limits.

<Cyclic Olefin-Based Film>

The cyclic olefin-based film according to the invention has an undercoat layer on at least one surface of a layer consisting of a cyclic olefin-based resin. In the undercoat layer, the content of the oxazoline group-containing polymer is 2 mass % to 15 mass %. The cyclic olefin-based film according to the invention has excellent dry adhesiveness and excellent wet adhesiveness.

The undercoat layer is a layer for providing a top coat layer, and the top coat layer and the undercoat layer are formed by coating, vapor deposition, or the like, and thus the top coat layer and the undercoat layer do not have the self-supporting properties. The thickness of the commercially available undercoat layer is 0.5 μm or less in many cases. In the case where the thickness of the undercoat layer is greater than 0.5 coating failure (coating unevenness, blocking of a film roll, rolling wrinkles, and the like) easily occurs. An adhesive or a pressure sensitive adhesive is refers to a material that adheres or bonds two products having self-supporting properties. For example, the adhesive or the pressure sensitive adhesive is used in order to adhere or bond polyvinyl alcohol (PVA) film and a triacetyl cellulose (TAC) film to each other. The thickness of the commercially available adhesive or the commercially available pressure sensitive adhesive is 1 μm to 10 as a dry film thickness, in many cases. The undercoat layer according to the invention is different from the adhesive layer or the pressure sensitive adhesive layer that is formed by coating the surface with the adhesive or the pressure sensitive adhesive, in view of film thickness.

The thickness of the undercoat layer according to the invention is preferably 500 nm or less, more preferably 20 nm to 400 nm, even more preferably 20 nm to 120 nm, even more preferably 20 nm to 95 nm, and particularly preferably 50 nm to 95 nm, as a dry film thickness.

Hereinafter, the layer consisting of the cyclic olefin-based resin in the cyclic olefin-based film and the undercoat layer according to the invention are described in detail.

<<Layer Consisting of Cyclic Olefin-Based Film>>

The cyclic olefin-based film according to the invention has the layer consisting of the cyclic olefin-based resin.

Preferable examples of the norbornene resin (norbornene unit) made of the raw material of the cyclic olefin-based resin include a saturated norbornene resin-A and a saturated norbornene resin-B described below. All of these saturated norbornene resins can be formed to films by a solution film forming method and a melting film forming method described below. However, the saturated norbornene resin-A is more preferably formed to a film by the melting film forming method, and the saturated norbornene resin-B is more preferably formed to a film by the melting and solution film forming method.

(Saturated Norbornene Resin-A)

Examples of the saturated norbornene resin-A include (1) a resin obtainable by hydrogenating a ring-opened (co)polymer of a norbornene-based monomer after performing polymer modification such as maleic acid addition and cyclopentadiene addition, if necessary, (2) a resin obtainable by performing addition polymerization to the norbornene-based monomer, and (3) a resin obtainable by performing addition copolymerization on a norbornene-based monomer and an olefin-based monomer such as ethylene or α-olefin. A polymerization method and a hydrogenation method can be performed in normal methods.

Examples of the norbornene-based monomer include norbornene, alkyl and/or alkylidene substitution products thereof (for example, 5-methyl-2-norbornene, 5-dimethyl-2-norbornene, 5-ethyl-2-norbornene, 5-butyl-2-norbornene, and 5-ethylidene-2-norbornene), and polar group substitution products of halogen thereof or the like; dicyclopentadiene, and 2,3-dihydrodicyclopentadiene; dimethanooctahydronaphthalene, alkyl and/or alkylidene substitution products thereof, and polar group substitution products of halogen or the like (for example, 6-methyl-1,4:5,8-dimethano-1,4,4a,5,6,7,8,8a-octahydronaphthalene, 6-ethyl-1,4:5,8-dimethano-1,4,4a,5,6,7,8,8a-octahydronaphthalene, 6-ethylidene-1,4:5,8-dimethano-1,4,4a,5,6,7,8,8a-octahydronaphthalene, 6-chloro-1,4:5,8-dimethano-1,4,4a,5,6,7,8,8a-octahydronaphthalene, 6-cyano-1,4:5,8-dimethano-1,4,4a,5,6,7,8,8a-octahydronaphthalene, 6-pyridyl-1,4:5,8-dimethano-1,4,4a,5,6,7,8,8a-octahydronaphthalene, and 6-methoxycarbonyl-1,4:5,8-dimethano-1,4,4a,5,6,7,8,8a-octahydronaphthalene); an adduct of cyclopentadiene and tetrahydroindene; and trimers or tetramers of cyclopentadiene (for example, 4,9:5,8-dimethano-3a,4,4a,5,8,8a,9,9a-octahydro-1H-benzoindene, and 4,11:5,10:6,9-trimethano-3a,4,4a,5,5a,6,9,9a, 10,10a,11,11a-dodecahydro-1H-cyclopentanthracene). These norbornene-based monomers may be used singly or two or more types thereof may be used in combination.

(Saturated Norbornene Resin-B)

Examples of the saturated norbornene resin-B include compounds expressed by General Formulae (1) to (4) below. Among these, compounds expressed by General Formula (1) below are particularly preferable.

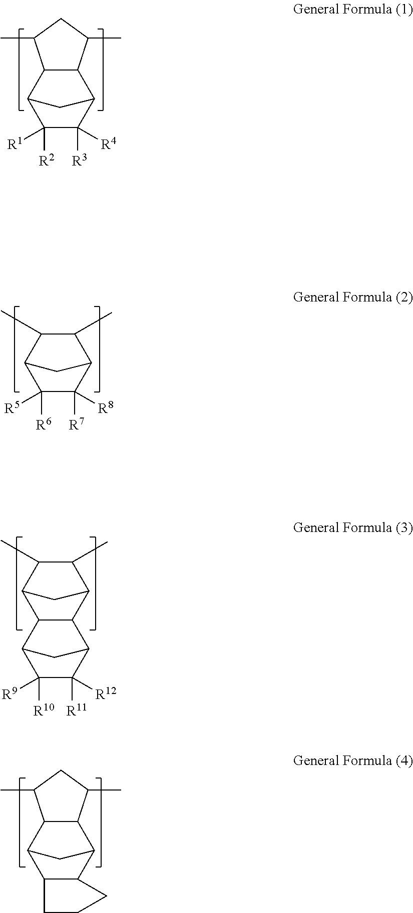

In General Formulae (1) to (4), each of R¹ to R¹² independently represents a hydrogen atom or a monovalent substituent (preferably an organic group), and at least one of these is preferably a polar group. In general, a weight-average molecular weight of these saturated norbornene resins is preferably 5,000 to 1,000,000 and more preferably 8,000 to 200,000.

Examples of the substituent above are substituents disclosed in paragraph “0036” of JP5009512B. Examples of the polar group above include polar groups disclosed in paragraph “0037” of JP5009512B.

Examples of the saturated norbornene resin that can be used in the invention include resins disclosed in JP1985-168708A (JP-S60-168708A), JP1987-252406A (JP-S62-252406A), JP1987-252407A (JP-S62-252407A), JP1990-133413A (JP-H02-133413A), JP1988-145324A (JP-S63-145324A), JP1988-264626A (JP-S63-264626A), JP1989-240517A (JP-H01-240517A), and JP1982-8815B (JP-S57-8815B).

Among these, a hydrogenated polymer obtained by hydrogenating a ring-opened polymer of a norbornene-based monomer is particularly preferable.

According to the invention, as the saturated norbornene resin, at least one type of the tetracyclododecene derivatives expressed by General Formula (5) below singly, or a hydrogenated polymer obtainable by hydrogenating a polymer obtainable by performing metathesis polymerization on the tetracyclododecene derivative above and an unsaturated cyclic compound copolymerizable with this tetracyclododecene derivative.

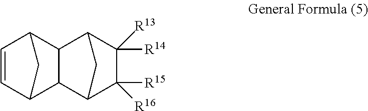

In General Formula (5), each of R¹³ to R¹⁶ independently represents a hydrogen atom or a monovalent substituent (preferably an organic group), and at least one of these is preferably a polar group. Specific examples and preferable ranges of the substituent and the polar group described herein are the same as described with respect to General Formulae (1) to (4).

With respect to the tetracyclododecene derivative expressed by General Formula (5) above, if at least one of R¹³ to R¹⁶ is a polar group, a polarizing film having excellent adhesiveness to other materials, excellent heat resistance, or the like can be obtained. It is preferable that this polar group is a group expressed by —(CH₂)ₙCOOR (here, R represents a hydrocarbon group having 1 to 20 carbon atoms, and n represents an integer of 0 to 10.), since a finally obtainable hydrogenated polymer (substrate of polarizing film) has a high glass transition temperature. Particularly, it is preferable that one of this polar substituent expressed by —(CH₂)ₙCOOR is contained in each one molecule of a tetracyclododecene derivative of General Formula (5), since water absorption is decreased. In the polar substituent above, as the number of carbon atoms of the hydrocarbon group expressed by R increases, it is more preferable since hygroscopicity of the obtainable hydrogenated polymer are small. However, in view of the balance with the glass transition temperature of the obtainable hydrogenated polymer, the hydrocarbon group above is preferably a chain alkyl group having 1 to 4 carbon atoms or a (poly)cyclic alkyl group having 5 or greater carbon atoms, and particularly preferably a methyl group, an ethyl group, and a cyclohexyl group.

A tetracyclododecene derivative of General Formula (5) in which, as a substituent, a hydrocarbon group having 1 to 10 carbon atoms is bonded to a carbon atom to which a group expressed by —(CH₂)ₙCOOR is bonded is preferable, since hygroscopicity of the obtainable hydrogenated polymer are low. Particularly, the tetracyclododecene derivative of General Formula (5) in which the substituent is a methyl group or an ethyl group is preferable since the synthesization thereof is easy. Specifically, 8-methyl-8-methoxycarbonyltetracyclo[4,4,0,1^{2.5},1^{7.10}]dodeca-3-ene is preferably. Mixtures of these tetracyclododecene derivatives and unsaturated cyclic compounds copolymerizable with the tetracyclododecene derivatives can be subjected to metathesis polymerization and hydrogenation, for example, by methods disclosed in line 12 on the upper right column of page 4 to line 6 on the lower right column of page 6 of JP 1992-77520A (JP-H04-77520A).

With respect to these norbornene-based resins, the intrinsic viscosity (ηᵢₙₕ) measured at 30° C. in chloroform is preferably 0.1 dl/g to 1.5 dl/g and even more preferably 0.4 dl/g to 1.2 dl/g. With respect to the hydrogenation rate of the hydrogenated polymer, the value measured with ¹H-NMR at 60 MHz is preferably 50% or greater, more preferably 90% or greater, and even more preferably 98% or greater. As the hydrogenation rate is higher, the obtainable saturated norbornene film has excellent stability to heat or light. A gel content included in the hydrogenated polymer is preferably 5 mass % or less and even more preferably 1 mass % or less.

(Other Ring-Opened Polymerizable Cycloolefines)

According to the invention, other ring-opened polymerizable cycloolefines can be used together. Specific examples of this cycloolefine include a compound having one reactive double bond such as cyclopentene, cyclooctene, or 5,6-dihydrodicyclopentadiene. The content of these ring-opened polymerizable cycloolefines is preferably 0 mol % to 50 mol %, more preferably 0.1 mol % to 30 mol %, and particularly preferably 0.3 mol % to 10 mol % with respect to the norbornene-based monomer above.

The cyclic olefin-based resin may be a cyclic olefin copolymer including an ethylene unit and a norbornene unit. The ethylene unit is a repeating unit expressed by —CH₂CH₂—. If the ethylene unit is subjected to vinyl polymerization with the norbornene unit described above, a cyclic olefin copolymer can be obtained. The copolymerization molar ratio of the norbornene unit and the ethylene unit is preferably 80:20 to 20:80, more preferably 80:20 to 50:50, and still more preferably 80:20 to 60:40.

The cyclic olefin copolymer may contain a small amount of the repeating unit consisting of other copolymerizable vinyl monomers other than the ethylene unit and the norbornene unit. Specific examples of the other vinyl monomer include α-olefin having 3 to 18 carbon atoms such as propylene, 1-butene, 1-hexene, 4-methyl-1-pentene, 1-octene, 1-decene, 1-dodecene, 1-tetradecene, 1-hexadecene, and 1-octadecene, and cycloolefine such as cyclobutene, cyclopentene, cyclohexene, 3-methylcyclohexene, and cyclooctene. These vinyl monomers may be used singly or two or more types thereof may be used in combination. The content of the repeating unit is preferably 10 mol % or less and more preferably 5 mol % or less with respect to the entire content.

(Other Additives)

Other additives may be added to the cyclic olefin-based resin without deteriorating the object of the invention. Examples of the additives include an antioxidant, an ultraviolet absorbent, a lubricant, and an antistatic agent. Particularly, in a case where the cyclic olefin-based resin is provided on front surfaces of various devices, the cyclic olefin-based resin preferably includes an ultraviolet absorbent. As the ultraviolet absorbent, a benzophenone-based ultraviolet absorbent, a benzotriazole-based ultraviolet absorbent, an acrylonitrile-based ultraviolet absorbent, and the like can be used.

The cyclic olefin-based resin is divided into an addition polymerization type and a ring-opening polymerization type, and both of the polymerization types can be used. Examples of the ring-opening polymerization-type cyclic olefin-based resin include ring-opening polymerization-type cyclic olefin-based resins disclosed in WO2009/041377A, WO2008/108199A, WO2007/001020A, WO2006/112304A, JP2008-037932A, WO2007/043573A, WO2007/010830A, JP5233280B, WO2007/001020A, JP2007-063356A, JP2009-210756A, JP2008-158088A, JP2001-356213A, JP2004-212848A, JP2003-014901A, JP2000-219752A, JP2005-008698A, WO2007/135887A, JP2012-056322A, JP1995-197623A (JP-H07-197623A), JP2006-215333A, JP2006-235085A, JP2005-173072A, JP4292993B, JP2004-258188A, JP2003-136635A, JP2003-236915A, JP1998-130402A (JP-H10-130402A), JP1997-263627A (JP-H09-263627A), JP1992-361230A (JP-H04-361230A), JP1992-363312A (JP-H04-363312A), JP1992-170425A (JP-H04-170425A), and JP1991-223328A (JP-H03-223328A).

Examples of the addition polymerization-type cyclic olefin-based resin include addition polymerization-type cyclic olefin-based resins disclosed in WO2009/139293A, WO2006/030797A, JP4493660B, JP2007-232874A, JP2007-009010A, WO2013/179781A, WO2012/114608A, WO2008/078812A, JP1999-142645A (JP-H11-142645A), JP1998-287713A (JP-H10-287713A), JP5220616B, JP1999-142645A (JP-H11-142645A), JP1998-258025A (JP-H10-258025A), JP2001-026682A, JP1993-025337A (JP-H05-025337A), and JP1991-273043A (JP-H03-273 043 A).

As the layer consisting of the cyclic olefin-based resin, commercially available cyclic olefin-based films can be used. Examples of the commercially available products include ARTON D4540 (manufactured by JSR Corporation).

The thickness of the layer consisting of the cyclic olefin-based resin is preferably 20 μm to 100 μm, more preferably 20 μm to 80 μm, and even more preferably 30 μm to 50 μm.

<<Undercoat Layer>>

The cyclic olefin-based film according to the invention has an undercoat layer on at least one surface of the layer consisting of the cyclic olefin-based resin, and the undercoat layer includes an oxazoline group-containing polymer.

If the undercoat layer formed on the surface of the layer consisting of the cyclic olefin-based resin includes the oxazoline group-containing polymer, it is possible to provide the cyclic olefin-based film having excellent dry adhesiveness and excellent wet adhesiveness.

If the undercoat layer contains the oxazoline group-containing polymer, the materials or the like is not particularly limited. Examples of the oxazoline group-containing polymer include polymers having an oxazoline group and a polyalkylene oxide chain, and even more preferably include an acryl polymer having an oxazoline group and a polyalkylene oxide chain. If necessary, the oxazoline group-containing polymer may include a binder or the like.

(Oxazoline Group-Containing Polymer)

The oxazoline group-containing polymer at least includes a monomer having an oxazoline group, as an essential component. If necessary, the oxazoline group-containing polymer can be easily prepared by polymerizing a monomer component including a monomer copolymerizable with a monomer having an oxazoline group.

Examples of the monomer having the oxazoline group include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, and 2-isopropenyl-5-methyl-2-oxazoline, and a mixture of one or more types thereof can be used. Among these, 2-isopropenyl-2-oxazoline can be easily obtainable in an industrial scale, and suitable.

According to the invention, an acryl monomer having a polyalkylene oxide chain is preferably used as a monomer component copolymerizable with a monomer having an oxazoline group, in view of solubility to water (a few organic solvents may be contained), cohesive force of an undercoat layer, and adhesiveness. That is, the oxazoline group-containing polymer is preferably an acryl polymer having an oxazoline group and a polyalkylene oxide chain.

Examples of the acryl monomer having the polyalkylene oxide chain include an acrylic acid or a methacrylic acid to which polyalkylene oxide is provided to an ester portion of an acrylic acid or a methacrylic acid. Examples of the polyalkylene oxide chain include polymethylene oxide, polyethylene oxide, polypropylene oxide, and polybutylene oxide. The repeating unit of the polyalkylene oxide chain is preferably 3 to 100. If the repeating unit of the polyalkylene oxide chain is smaller than 3, the transparency of the undercoat layer becomes worse. If the repeating unit is greater than 100, the wet heat resistance of the undercoat layer decreases, adhesiveness is deteriorated under high humidity and high temperature. The ratio of the monomer having the oxazoline group and the acryl monomer having the polyalkylene oxide chain is preferably 1:1 to 5:1. If the amount of the oxazoline group (the amount of the monomer having the oxazoline group) is less than 1:1, the adhesiveness decreases, and if the amount of the oxazoline group is greater than 5:1, the solubility to water is deteriorated.

Monomers other than the above can be appropriately used as other copolymerizable monomer components. Examples thereof include alkyl acrylate, alkyl methacrylate (a methyl group, an ethyl group, an n-propyl group, an isopropyl group, an n-butyl group, an isobutyl group, a t-butyl group, a 2-ethylhexyl group, and a cyclohexyl group, as an alkyl group); a hydroxy-containing monomer such as 2-hydroxyethyl acrylate, 2-hydroxyethyl methacrylate, 2-hydroxypropyl acrylate, and 2-hydroxypropyl methacrylate; an epoxy group-containing monomer such as glycidyl acrylate, glycidyl methacrylate, and allyl glycidyl ether; a monomer having a carboxyl group or salts thereof such as an acrylic acid, a methacrylic acid, an itaconic acid, a maleic acid, a fumaric acid, a crotonic acid, a styrenesulfonic acid and salts thereof (a sodium salt, a potassium salt, an ammonium salt, and a tertiary amine salt); a monomer having an amide group such as acrylamide, methacrylamide, N-alkylacrylamide, N-alkylmethacrylamide, N,N-dialkylacrylamide, N,N-dialkyl methacrylate (a methoxy group, an ethoxy group, a butoxy group, and an isobutoxy group, as an alkoxy group), acryloylmorpholine, N-methylolacrylamide, N-methylolmethacrylamide, N-phenylacrylamide, and N-phenylmethacrylamide; a monomer of an acid anhydride such as a maleic anhydride and an itaconic anhydride; vinylisocyanate, allylisocyanate, styrene, α-methylstyrene, vinyl methyl ether, vinyl ethyl ether, vinyl trialkoxy silane, alkyl maleic acid monoester, alkyl fumaric acid monoester, alkyl itaconic acid monoester, acrylonitrile, methacrylonitrile, vinylidene chloride, ethylene, propylene, vinyl chloride, vinyl acetate, and butadiene.

As the acryl polymer having the oxazoline group and the polyalkylene oxide chain, commercially available products can be used, and examples thereof include EPOCROS K-2010E, EPOCROS K-2020E, EPOCROS K-2030E, EPOCROS WS-700, and EPOCROS WS-300 (all are manufactured by Nippon Shokubai Co., Ltd.).

The content of the oxazoline group-containing polymer in the undercoat layer is 2 mass % to 15 mass %, preferably 3 mass % to 12 mass %, and particularly preferably 5 mass % to 10 mass %.

If the content of the oxazoline group-containing polymer is less than 2 mass %, the cohesive force of the undercoat layer decreases, such that the adhesiveness becomes insufficient, in some cases. If the content of the oxazoline group-containing polymer is greater than 15 mass %, the adhesiveness of the layer consisting of the cyclic olefin-based resin decreases in some cases.

The content of the oxazoline group-containing polymer in the undercoat layer can be obtained from absorption peak strength derived from the oxazoline group and absorption peak strength derived from the other binders, by sampling the undercoat layer composition, analyzing the undercoat layer composition by ¹H-NMR.

The oxazoline group-containing polymer in the undercoat layer includes the polymer in which the oxazoline group in the polymer is not reacted so as to form a closed ring, the polymer in which the oxazoline group in the polymer is not crosslinked so as to form an open ring, and the oxazoline group in the polymer is reacted and crosslinked so as to be amide esterified. The content of all the polymers described above can be checked by ¹H-NMR.

In view of the burden on the environment, the oxazoline group-containing polymer is preferably water soluble.

In view of increasing the adhesiveness of the layer consisting of the cyclic olefin-based resin, the glass transition temperature (Tg) of the oxazoline group-containing polymer is preferably 50° C. or greater and more preferably 85° C. or greater. The upper limit thereof is not particularly limited, but is 150° C. In general, it is considered that, as the adhesive layer is softer (that is, as Tg is lower), the adhesive force increases. However, the fact that it is more preferable to use the oxazoline group-containing polymer having comparatively high Tg of 50° C. or greater according to the invention was unexpected. For example, the glass transition temperature can be measured by differential scanning calorimetry (DSC).

The weight-average molecular weight of the oxazoline group-containing polymer is not particularly limited, but the weight-average molecular weight thereof is preferably 40,000 or greater, more preferably 40,000 to 200,000, and even more preferably 70,000 to 150,000. For example, the weight-average molecular weight is measured by gel permeation chromatography (GPC).

The undercoat layer according to the invention promotes crosslinking reaction with the oxazoline group-containing polymer, and thus catalysts such as an onium compound or a water miscible organic solvent may be added.

—Onium Compound—

The undercoat layer according to the invention contains at least one type of the onium compounds. If the onium compound is contained, the crosslinking reaction between the polymer and the oxazoline group-containing polymer is promoted, such that the improvement of the solvent resistance is achieved. If the crosslinking favorably proceeds, the adhesiveness between the undercoat layer and the layer consisting of the cyclic olefin-based resin becomes excellent.

Examples of the onium compound suitably include an ammonium salt, a sulfonium salt, an oxonium salt, an iodonium salt, a phosphonium salt, a nitronium salt, a nitrosonium salt, and a diazonium salt.

Specific examples of the onium compound include ammonium salts such as monoammonium phosphate, diammonium phosphate, ammonium chloride, ammonium sulfate, ammonium nitrate, p-toluenesulfonic acid ammonium, ammonium sulfamate, an ammonium imidodisulfonate, tetrabutylammonium chloride, benzyltrimethylammonium chloride, triethylbenzylammonium chloride, tetrabutylammonium tetrafluoroborate, tetrabutylammonium hexafluorophosphate, tetrabutylammonium perchlorate, and tetrabutylammonium sulfate; sulfonium salts such as trimethylsulfonium iodide, trimethyl sulfonium tetrafluoroborate, diphenylmethylsulfonium tetrafluoroborate, benzyltetramethylenesulfonium tetrafluoroborate, antimony 2-butenyltetramethylenesulfonium hexafluoride, and antimony 3-methyl-2-butenyltetramethylenesulfonium hexafluoride; an oxonium salt such as trimethyloxonium tetrafluoroborate; an iodonium salt such as diphenyliodonium chloride and diphenyliodonium tetrafluoroborate; phosphonium salt such as antimony cyanomethyltributylphosphonium hexafluoride, and ethoxycarbonylmethyltributylphosphonium tetrafluoroborate; a nitronium salt such as nitronium tetrafluoroborate; a nitrosonium salt such as nitrosonium tetrafluoroborate; and a diazonium salt such as 4-methoxybenzenediazonium chloride.

Among these, as the onium compound, in view of the reduction of the curing time, an ammonium salt, a sulfonium salt, an iodonium salt, and a phosphonium salt are more preferable. Among these, the ammonium salt is even more preferable. In view of safety, pH, and cost, phosphoric acid-based and benzyl chloride-based onium compounds are preferable.

The onium compound in the undercoat layer may be used singly, or two or more types thereof may be used in combination.

The content of the onium compound in the undercoat layer is preferably in the range of 0.1 mass % to 15 mass %, more preferably in the range of 0.5 mass % to 10 mass %, and even more preferably in the range of 1 mass % to 5 mass % with respect to the binder amount of the undercoat layer. The fact that the content of the onium compound is 0.1 mass % or greater means that the onium compound is positively contained. The crosslinking reaction between the binder and the oxazoline group-containing polymer more favorably proceeds by containing the onium compound such that more excellent solvent resistance can be obtained. If the content of the onium compound is 15 mass % or less, it is advantageous in view of solubility, filtration performances, and adhesion.

—Water Miscible Organic Solvent—

The undercoat layer according to the invention may contain at least one water miscible organic solvent having a boiling point of 99° C. or less. If the organic solvent having a low boiling point is contained, the crosslinking reaction between the binder and the oxazoline group-containing polymer is promoted, such that the solvent resistance increases.

The water miscible properties refer to properties having water solubility and refer to properties of being arbitrarily mixed with water.

The fact that the boiling point is 99° C. or less means that the organic solvent is more easily removed compared with water which is a main solvent in the coating liquid prepared in an aqueous system. It is assumed that, if the solvent component that more easily comes out of the system than water is included, the crosslinking reaction becomes more favorable.

The water miscible organic solvent having the boiling point of 99° C. or less is not particularly limited other than the boiling point, and examples thereof include an alcohol-based solvent (monovalent alcohol and polyhydric alcohol which is divalent or higher), a ketone-based solvent, an ether-based solvent, and an ester-based solvent.

Examples of the alcohol-based solvents include methyl alcohol (b.p: 65° C.), ethyl alcohol (b.p: 78° C.), n-propyl alcohol (b.p: 97° C.), i-propyl alcohol (b.p: 82° C.), and t-butyl alcohol (b.p: 82° C.), and suitably include the monovalent alcohol having 1 to 3 carbon atoms. Examples of the ketone-based solvent include the ketone-based compound having 3 to 5 carbon atoms such as acetone (b.p: 56° C.), methyl ethyl ketone (b.p: 80° C.), 2-butanone (b.p: 79.5° C.). Examples of the ether-based solvent include diethyl ether (b.p: 35° C.) and tetrahydrofuran (b.p: 66° C.). Examples of the ester-based solvent include ethyl acetate (b.p: 70° C.) and isopropyl acetate (b.p: 88° C. to 91° C.). The expression “b.p” refers to a boiling point.

Among these, in view of the crosslinking reaction properties between the binder and the oxazoline group-containing polymer and the enhancement of the solvent resistance properties, the water miscible organic solvent is preferably the solvent selected from the monovalent alcohol having 1 to 3 carbon atoms and the ketone-based compound having 3 to 5 carbon atoms, and more preferably methyl alcohol, ethyl alcohol, n-propyl alcohol, i-propyl alcohol, and acetone.

The water miscible organic solvent may be included in the undercoat layer according to the invention, and the content of the water miscible organic solvent contained in the undercoat layer is preferably 0.0001 mass % to 30 mass % and more preferably 0.1 mass % to 5 mass % with respect to the binder amount in the polymer layer.

Since the water miscible organic solvent volatilizes, the storage environment thereof is desirably at room temperature, within one week, and in an air tight container.

The amount of the water miscible organic solvent included in the undercoat layer is a value quantified by using a non-polar column as a column and by performing detection by the gas chromatography method.

(Binder)

The undercoat layer may contain a binder in addition to the oxazoline group-containing polymer.

Examples of the binder suitable for the undercoat layer include at least one resin selected from a polyolefin resin, an acryl resin, a modified silicone resin, a polyester resin, a polyurethane resin, or a styrene butadiene rubber resin. Among these, in view of adhesiveness, an acryl resin, a polyester resin, a polyurethane resin, and a styrene butadiene rubber resin are preferable, and a polyurethane resin is particularly preferable.

The polyolefin resin that can be used in the invention is a resin having polyolefin such as polyethylene and polypropylene in a main chain skeleton. Specific examples of the main chain include an ethylene-(meth)acrylic acid copolymer, an ethylene-(meth)acrylic acid ester-(meth)acrylic acid copolymer, an ethylene-vinyl acetate copolymer, an ethylene-vinyl acetate-(meth)acrylic acid copolymer, an ethylene-propylene-(meth)acrylic acid copolymer, an ethylene-propylene-(meth)acrylic acid ester-(meth)acrylic acid copolymer, an ethylene-maleic anhydride copolymer, an ethylene-(meth)acrylic acid ester-maleic anhydride copolymer, an ethylene-butene-maleic anhydride and/or-(meth)acrylic acid copolymer, a propylene-butene-maleic anhydride and/or-(meth)acrylic acid copolymer, an ethylene-vinyl chloride copolymer, an ethylene-vinyl chloride copolymer, and an ethylene-(meth)acrylic acid copolymer. Examples of the polyolefin-based resin that is commercially obtainable include AROBASE SE-1010, SE-1013N, SD-1010, TC-4010, TD-4010 (above are manufactured by Unitika, Ltd.), HITEC 53148, 53121, and 58512 (above are manufactured by TOHO Chemical Industry Co., Ltd.), and CHEMIPEARL S-120, S-75N, V100, and EV210H (above are manufactured by Mitsui Chemicals Tohcello, Inc.). Among these, according to the invention, AROBASE SE-1013N (manufactured by Unitika, Ltd.) is preferably used.

The acryl resin that can be used in the invention may be a polymer obtained by polymerizing an acryl monomer such as polymethyl methacrylate, polyethyl methacrylate, and polymethyl acrylate, and may be a resin obtained by copolymerizing an acrylic acid and a methacrylic acid, if necessary. Examples of the commercially obtainable acryl resin include AS-563A (manufactured by Daicel Finechem Ltd.), JURYMER ET410, JURYMER SEK301, and JURYMER FC30 (manufactured by Nihon Junyaku Co., Ltd.).

Examples of the modified silicone resin that can be used in the invention include a composite resin of acryl and silicone. Specific examples of the commercially obtainable modified silicone resin include CERANATE WSA1060 and WSA1070 (all are manufactured by DIC Corporation) and H7620, H7630, and H7650 (all are manufactured by Asahi Kasei Chemicals Corporation).

Examples of the polyester resin that can be used in the invention include polyester such as polyethylene terephthalate (PET) and polyethylene-2,6-naphthalate (PEN). Examples of the commercially obtainable polyester resin include VYLONAL MD1400, MD1480, and MD1245 (manufactured by TOYOBO Co., Ltd.) and PLASCOAT Z-221, Z-561, Z-730, RZ-142, and Z-687 (manufactured by Goo Chemical Co., Ltd.).

As the polyurethane resin that can be used in the invention, carbonate-based, ether-based, and ester-based polyurethane resins can be used. Particularly, in view of adhesiveness, a self-crosslinking-type polyurethane resin is preferable. Examples of the commercially obtainable polyurethane resin include SUPERFLEX 830, 460, 870, 420, and 420NS (polyurethane manufactured by DKS Co., Ltd.), HYDRAN AP-40F, WLS-202, and HW-140SF (polyurethane manufactured by DIC Corporation), OLESTER UD500 and UD350 (polyurethane manufactured by Mitsui Chemicals, Inc.), TAKELAC W-615, W-6010, W-6020, W-6061, W-405, W-5030, W-5661, W-512A-6, W-635, and WPB-6601, and examples thereof particularly include self-crosslinking-type WS-6021, WS-5000, WS-5100, WS-4000, WSA-5920, and WF-764 (manufactured by Mitsui Chemicals, Inc.).

Examples of the styrene butadiene rubber resin that can be used in the invention include styrene, butadiene, acrylonitrile, methyl methacrylate, and examples of the commercially obtainable styrene butadiene rubber resin include NIPOL LX415, NIPOL LX407, NIPOL V1004, NIPOL MI-18101, and SX1105 (manufactured by ZEON Corporation).

The content ratio of the binder in the undercoat layer is preferably 70 mass % to 97 mass % and particularly preferably 75 mass % to 98 mass %.

(Other Additives)

In addition to the oxazoline group-containing polymer and the binder, the undercoat layer may contain other additives, if necessary. Examples of the other additives include an aliphatic wax (slipping agent), filler, and a surfactant.

The content of the aliphatic wax in the undercoat layer is preferably 0.5 mass % to 30 mass % and more preferably 1 mass % to 10 mass %. If the ratio thereof is less than 0.5 mass %, the slippage of the film surface cannot be obtained. If the ratio thereof is greater than 30 mass %, adhesion to the substrate or easy adhesiveness of the cyclic olefin-based film become insufficient in some cases.

Specific examples of the aliphatic wax include plant-derived waxes such as a carnauba wax (examples of the commercially available product include SELOSOL 524, manufactured by Chukyo Yushi Co., Ltd.), a candelilla wax, a rice wax, a Japan wax, jojoba oil, a palm wax, a rosin-modified wax, an ouricury wax, a sugar cane wax, an esparto wax, and a bark wax, animal-derived waxes such as beeswax, lanolin, spermaceti, an insect wax, and a shellac wax, mineral-derived waxes such as a montan wax, ozokerite, and a ceresin wax, petroleum-derived waxes such as a paraffin wax, a microcrystalline wax, and petrolatum, and synthetic hydrocarbon-based waxes such as a Fischer-Tropsch wax, a polyethylene wax, an oxidized polyethylene wax, a polypropylene wax, and an oxidized polypropylene wax. Further, since the easy adhesiveness and the slippage are favorable, a carnauba wax, a paraffin wax and a polyethylene wax are more preferable. Particularly, aqueous dispersion is more preferable in view of the burden on the environment and easy handling.

In the undercoat layer, it is preferable to cause filler having an average particle diameter of 0.005 μm to 0.5 μm to be contained at 0.1 mass % to 20 mass %. If the content of the filler in the coating layer is less than 0.1 mass %, the slippage of the film becomes insufficient, such that winding the film in a roll shape becomes difficult. If the content of the filler is greater than 20 mass %, the transparency of the undercoat layer becomes insufficient, such that the film may not be used for a display.

Examples of the filler include colloidal silica (examples of the commercially available product include SNOWTEX UP, manufactured by Nissan Chemical Industries, Ltd.), inorganic fine particles such as calcium carbonate, magnesium carbonate, calcium oxide, zinc oxide, magnesium oxide, silicon oxide, sodium silicate, aluminum hydroxide, iron oxide, zirconium oxide, barium sulfate, titanium oxide, tin oxide, antimony trioxide, carbon black, and molybdenum disulfide, and organic fine particles such as an acrylic crosslinked polymer, a styrene-based crosslinked polymer, a silicone resin, a fluorine resin, a benzoguanamine resin, a phenol resin, a nylon resin, and a polyethylene wax. Among these, as water insoluble solid substances, ultrafine particles having specific weight of not greater than 3 are preferably selected, in order to prevent the water insoluble solid substances from being precipitate in aqueous dispersant.

In view of improving coating properties, various surfactants may be added to the undercoat layer. As the surfactant, various surfactants such as a fluorine-based surfactant, a nonionic surfactant, a cationic surfactant, an anionic surfactant, and a silicone-based surfactant can be used.

Examples of the fluorine-based surfactant include MEGAFACE F171, MEGAFACE F172, MEGAFACE F173, MEGAFACE F176, MEGAFACE F177, MEGAFACE F141, MEGAFACE F142, MEGAFACE F143, MEGAFACE F144, MEGAFACE R30, MEGAFACE F437, MEGAFACE F475, MEGAFACE F479, MEGAFACE F482, MEGAFACE F554, MEGAFACE F780, and MEGAFACE F781 (above are manufactured by DIC Corporation), FLUORAD FC430, FLUORAD FC431, and FLUORAD FC171 (above are manufactured by Sumitomo 3M Limited), SURFLON S-382, SURFLON SC-101, SURFLON SC-103, SURFLON SC-104, SURFLON SC-105, SURFLON SC1068, SURFLON SC-381, SURFLON SC-383, SURFLON 5393, and SURFLON KH-40 (above are manufactured by Asahi Glass Co., Ltd.), and PF636, PF656, PF6320, PF6520, and PF7002 (manufactured by OMNOVA Solutions Inc.).

Specific examples of the nonionic surfactant include glycerol, trimethylol propane, trimethylol ethane, and ethoxylates and propoxylates thereof (for example, glycerol propoxylate and glycerin ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, and sorbitan fatty acid esters (PLURONIC L10, L31, L61, L62, 10R5, 17R2, and 25R2, TETRONIC 304, 701, 704, 901, 904, and 150R1, manufactured by BASF SE, PIONIN D-6512, D-6414, D-6112, D-6115, D-6120, D-6131, D-6108-W, D-6112-W, D-6115-W, D-6115-X, and D-6120-X (manufactured by Taketomo Oil & Fat Co., Ltd.), SOLSPERSE 20000 (manufactured by The Lubrizol Corporation), and NAROACTY CL95 and HN-100 (manufactured by Sanyo Chemical Industries, Ltd.).

Specific examples of the cationic surfactant include phthalocyanine derivatives (Product name: EFKA-745, manufactured by Morishita & Co., Ltd.), organosiloxane polymer KP341 (manufactured by Shin-Etsu Chemical Co., Ltd.), (meth)acrylic acid-based (co)polymer POLYFLOW No. 75, No. 90, No. 95 (manufactured by Kyoeisha Chemical Co., Ltd.), and W001 (manufactured by Yusho Co. Ltd.).

Specific examples of the anionic surfactant include W004, W005, and W017 (manufactured by Yusho Co. Ltd.), SANDET BL (manufactured by Sanyo Chemical Industries, Ltd.), and LUPIZOL A-90 (manufactured by NOF Corporation).

Examples of the silicone-based surfactant include “TORAY SILICONE DC3PA”, “TORAY SILICONE SH7PA”, “TORAY SILICONE DC11PA”, “TORAY SILICONE SH21PA”, “TORAY SILICONE SH28PA”, “TORAY SILICONE SH29PA”, “TORAY SILICONE SH30PA”, and “TORAY SILICONE SH8400” manufactured by Dow Corning Corporation, “TSF-4440”, “TSF-4300”, “TSF-4445”, “TSF-4460”, and “TSF-4452” manufactured by Momentive Performance Materials Inc., “KP341”, “KF6001”, and “KF6002” manufactured by Shin-Etsu Chemical Co., Ltd., and “BYK307”, “BYK323”, and “BYK330” manufactured by BYK Japan KK.

The surfactants may be used singly or two or more types thereof may be used in combination.

The addition amount of the surfactant is preferably 0.001 mass % to 2.0 mass % and more preferably 0.005 mass % to 1.0 mass % with respect to the total mass of the coating liquid for forming the undercoat layer (hereinafter, referred to as a “coating liquid for undercoat layer”).

<Manufacturing of Cyclic Olefin-Based Film>

The cyclic olefin-based film according to the invention can be manufactured by producing the layer consisting of the cyclic olefin-based resin and providing the undercoat layer on at least one surface of the layer consisting of the cyclic olefin-based resin. More specifically, the undercoat layer can be formed by coating at least one surface of the layer consisting of the cyclic olefin-based resin with the coating liquid at least including the oxazoline group-containing polymer and the resin and then curing the coating liquid.

The cyclic olefin-based film according to the invention can be manufactured in all methods of a solution film forming method and a melting film forming method, but the melting film forming method is more preferable.

<<Melting Film Forming Method>>

In the melting film forming method, before the film is formed, other additives are added, if necessary, and the resin is dried. The preferable drying condition is 80° C. to Tg of the resin and more preferably 100° C. to Tg−5° C. The preferable drying time is 0.5 hours to 24 hours and more preferably 1 hour to 10 hours.

(Extrusion)

As types of extruders, a single screw extruder having relatively inexpensive equipment cost is used in many cases. Examples thereof include screw types such as a full flight type, a maddock type, and a dulmage type, but the full flight type is preferable. If a screw segment is changed, a twin screw extruder in which a ventilation opening is provided in the middle and extrusion can be performed while unnecessary volatile components are devolatilized can be used. The twin screw extruder is greatly classified into a same direction type and a different direction type, and the both types can be used. However, a same direction rotation type that hardly generates remaining portions and that has excellent cleaning performance is preferable.

(Filtration)

In order to filter foreign substances in the resin or to avoid damages in a gear pump caused by the foreign substances, it is preferable to perform so-called breaker plate-type filtration performed by providing a filter filtration medium at an outlet of the extruder. In order to highly accurately filter foreign substances, it is preferable to provide a filtration device in which a leaf-type disc filter is combined after the passage of the gear pump. The filtration can be performed by providing one filtration portion, or may be a multi-stage filtration performed by providing plural filtration portions. It is preferable that the filtration accuracy of the filter filtration medium is high. However, in view of pressure resistance of the filtration medium and filtration pressure increase due to clogging of the filtration medium, the filtration accuracy is preferably 15 μm to 3 μm and even more preferably 10 μm to 3 μm. In a case where a leaf-type disc filter device that finally performs foreign substance filtration is used, it is particularly preferable to use a filtration medium having high filtration accuracy, and it is possible to adjust the number of charged sheets in order to secure pressure resistance and aptitude of filter life. With respect to the types of the filtration medium, in view of the use at high temperature and high pressure, a steel material is preferably used. Among steel materials, stainless steel, steel, and the like are particularly preferably used. In view of corrosion, stainless steel is particularly desirably used. As the configuration of the filtration medium, in addition to weaving wire materials, a sintered filtration medium formed by sintering metal long fibers or metal powders can be used. In view of the filtration accuracy and the filter life, the sintered filtration medium is preferable.

(Gear Pump)

It is preferable that a gear pump is provided between the extruder and the dice, and a given amount of resin is supplied from the gear pump. The discharge fluctuation can be given by giving a fluctuation to the number of rotations. The gear pump containing a pair of gears consisting of a driving gear or a driven gear in a state of being engaged with each other, rotating both gears in an engaged manner by driving the driving gear so as to suck the resin in the melt state from a suction port formed in a housing into a cavity, and discharging a given amount of the resin from the discharging opening formed in the housing in the same manner.

(Die)

The resin is melt by the extruder formed as described above, and the melt resin is continuously sent to the die via a filtering machine and a gear pump, if necessary. As the die, all types of dies that are a T die, a fishtail die, and a hanger coat die that are generally used can be used. Immediately before the die, a static mixer for increasing evenness of the resin temperature can be interposed therebetween.

(Casting)

In the method described above, the melt resin extruded to the sheet by the die is cooled and solidified on the casting drum, so as to obtain an un-stretched film. At this point, it is preferable to increase the adhesion between the casting drum and the melt and extruded sheet by using the method of an electrostatic application method, an air knife method, an air chamber method, a vacuum nozzle method, a touch roller method, and the like. This adhesion increase method can be performed on the entire surface of the melt and extruded sheet or on a portion thereof. Particularly, a method of adhering only both ends of the film, so-called edge pinning, is performed in many cases, but the invention is not limited thereto.

It is more preferable to perform slow cooling by using plural casting drums. In general, the slow cooling using three cooling rollers is relatively frequently performed, but the invention is not limited thereto. The diameter of the roller is preferably 50 mm to 5,000 mm, and the interval of the plural rollers is preferably 0.3 mm to 300 mm from surface to surface.

The casting drum is preferably Tg−70° C. to Tg+20° C. of the resin, more preferably Tg−50° C. to Tg+10° C., and even more preferably Tg−30° C. to Tg+5° C.

In a case where a so-called touch roller method, the front surface of the touch roller may be rubber or a resin such as TEFLON (registered trademark) or may be a metal roller. If the thickness of the metal roll is caused to be thin, the front surface of the roller is slightly depressed due to the pressure at the time of the touch, the pressure bonding area increases, and thus a roller called a flexible roller can be used.

The touch roller temperature is preferably Tg−70° C. to Tg+20° C., more preferably Tg−50° C. to Tg+10° C., and even more preferably Tg−30° C. to Tg+5° C.

(Stretching)

The casting film (un-stretched raw film) extruded to the casting drum as described above may be stretched in at least one axis direction of the vertical direction (MD) or the horizontal direction (TD). It is more preferable that the casting film is biaxially stretched in the vertical direction (MD) and the horizontal direction (TD). In a case where the casting film is biaxially stretched in the vertical direction and the horizontal direction, the stretching may be performed sequentially such as vertical to horizontal or horizontal to vertical, or the stretching may be performed in two directions at the same time. It is preferable that stretching is performed in multiple stages, for example, vertically, vertically, and horizontally; vertically, horizontally, and vertically; or vertically, horizontally, and horizontally.

The vertical stretching can be obtained by generally installing two pairs or more nip rollers, causing the raw film to pass through the nip rollers, and causing a circumferential speed of the nip rollers on the outlet side to be faster than that of the nip rollers on the inlet side.

It is preferable to perform cross-direction stretching by using a tenter. That is, the cross-direction stretching can be performed by transporting heating zones while both ends of the film are grabbed with clips and widening the clips in a width direction.

The preferable stretching ratio is preferably 1.05 times to 8 times and more preferably 1.1 times to 6 times in vertical and horizontal directions, respectively, and the stretching temperature is Tg−20° C. to Tg+80° C. and more preferably Tg° C. to Tg+50° C. Accordingly, the birefringence can be exhibited, brittleness can be improved, or the film can be thinned.

Before the vertical and horizontal stretching, the film may be preheated. The preheating temperature is preferably Tg−50° C. to Tg+30° C., more preferably Tg−40° C. to Tg+15° C., and even more preferably Tg−30° C. to Tg of the resin. The preheating like this may be performed by bringing the film in contact with a heating roller, by using a radiation heat source (a IR heater, a halogen heater, or the like), or by blowing hot air.

After the vertical and horizontal stretching treatments, the heat treatment may be performed to the film. The heat treatment refers to heating the film at about Tg+10° C. to Tg+50° C. (more preferably, at Tg+15° C. to Tg+30° C.) for 1 second to 60 seconds (more preferably for 2 seconds to 30 seconds). At this point, the film may be relaxed by vertically and horizontally shrinking the film. The preferably relaxation rate is 0.5% to 10% in one or both directions of the vertical and horizontal directions.

The heat treatment refers to performing a heat treatment at about Tg+10° C. to Tg+50° C. (more preferably Tg+15° C. to Tg+30° C.) for 1 second to 60 seconds (more preferably 2 seconds to 30 seconds) on the film. After the cross-direction stretching, the heat fixing is preferably performed in a state in which the film is grabbed by chucks in the tenter, and the interval of the chucks at this point may be a width when the cross-direction stretching is ended, or may be widened or shortened. It is possible to adjust Re and Rth to be in the ranges according to the invention, by performing the heat treatment.

(Forming of Undercoat Layer)

For example, the undercoat layer according to the invention can be formed, for example, by coating at least one surface of the layer consisting of the cyclic olefin-based resin with the coating liquid for undercoat layer containing the oxazoline group-containing polymer and the binder.

For example, as the coating method, well-known coating methods such as a gravure coater or a bar coater can be used. With respect to the timing for coating, an off-line coating method or an in-line coating method may be used.

The coating liquid may be aqueous liquid in which water is used as the coating solvent or may be the solvent-based liquid in which an organic solvent such as methyl ethyl ketone is used. Among these, in view of the burden on the environment, it is preferable to use water as the solvent. The coating solvents may be used singly or two or more types thereof may be used in combination.

The coating amount of the undercoat layer coating liquid is preferably 0.5 g/m² or greater and more preferably 3 g/m² or greater. The upper limit thereof is not particularly limited, but is 50 g/m² or less.

After coating is performed with the undercoat layer coating liquid, the undercoat layer can be formed by curing the undercoat layer coating liquid by heating. The heating method is not particularly limited, but the film surface temperature is preferably 50° C. to 150° C. and more preferably 60° C. to 120° C., and the heating is performed preferably for 30 seconds to 5 minutes and more preferably 30 seconds to 3 minutes.

Before the at least one surface of the layer consisting of the cyclic olefin-based resin is coated with the coating liquid for undercoat layer, treatments such as saponification, a corona treatment, a flame treatment, a glow discharge treatment may be performed on the film surface, in order to increase the adhesiveness on the coating surface of the cyclic olefin-based film.

(Winding)

After the film is formed and stretched, it is preferable that both ends thereof are trimmed, and the film is wound. The trimmed portions may be subjected to a pulverization treatment or a granulation treatment, if necessary, and may be reused as the raw material for the film in the same type or as the raw material for the film in the different type. As a trimming cutter, all types of cutters such as a rotary cutter, a shear blade, or a knife can be used. With respect to the materials, both of carbon steel and stainless steel can be used. In general, if a cemented carbide blades or a ceramic blade is used, it is preferable since a life span of the cutter is long.

It is preferable to attach a laminate film on at least one surface before the winding, in view of preventing scratches. The preferable winding tension is 1 kg/m to 50 kg/m in width, more preferably 2 kg/m to 40 kg/m in width, and even more preferably 3 kg/m to 20 kg/m in width. If the winding tension is 1 kg/m or greater of the width, it is preferable since it is easy to evenly wind the film. If the winding tension is 50 kg/m or less in width, the film is not rolled and the winding appearance can be maintained to be beautiful.

<<Solution Film Forming Method>>

(Film Formation)

When the cyclic olefin-based film is formed by the solution film forming method, the resins are first dissolved in the solvent. The total concentration of the resins when being dissolved in the solvent is preferably 3 mass % to 50 mass %, more preferably 5 mass % to 40 mass %, and even more preferably 10 mass % to 35 mass %. The viscosity of the obtained solution at the room temperature is generally 1 to 1,000,000 (mPa·s), preferably 10 to 100,000 (mPa·s), even more preferably 100 to 50,000 (mPa·s), and particularly preferably 1,000 to 40,000 (mPa·s).

As the used solvent, aromatic solvents such as benzene, toluene, and xylene, a cellosolve-based solvent such as methyl cellosolve, ethyl cellosolve, and 1-methoxy-2-propanol, a ketone-based solvent such as diacetone alcohol, acetone, cyclohexanone, methyl ethyl ketone, 4-methyl-2-pentanone, ethylcyclohexanone, and 1,2-dimethylcyclohexane, an ester-based solvent such as methyl lactate and ethyl lactate, a halogen-containing solvent such as 2,2,3,3-tetrafluoro-1-propanol, methylene chloride, and chloroform, an ether-based solvent such as tetrahydrofuran, and dioxane, and an alcohol-based solvent such as 1-pentanol and 1-butanol.

In addition to the above, it is preferable to use the solvent having an SP value (solubility parameter) of generally 10 to 30 (MPa^{1/2}). The solvent may be used singly or two or more types thereof may be used in combination. In the case where two or more types of the solvents are used together, the range of the SP values as the mixture is preferably in the range described above. At this point, the SP value as the mixture can be obtained from the mass ratio thereof. For example, in the case of the mixture of two types, when mass fractions of the respective solvents are set to be W1 and W2, and the SP values are set to be SP1 and SP2, the SP values of the mixed solvents can be obtained as values calculated by the equation below.

SP value=W1·SP1+W2·SP2

In order to improve the surface smoothness of the cyclic olefin-based film, a leveling agent may be added. All types of general leveling agents can be used, and, for example, a fluorine-based nonionic surfactant, a specific acryl resin-based leveling agent, a silicone-based leveling agent, and the like can be used.

Examples of the method for manufacturing the cyclic olefin-based film by the solvent casting method generally include a method of coating the substrate such as a metal drum, a steel belt, a film of polyester such as polyethylene terephthalate (PET) or polyethylene naphthalate (PEN), and a belt made of polytetrafluoroethylene, with the solution by using the dice or the coater, drying and removing the solvent, and peeling the film from the substrate.

The cyclic olefin-based film is manufactured by coating the substrate with the resin solution by using means such as a spray, a brush, roll spin coating, and dipping, drying and removing the solvent, and peeling the film from the substrate. Further, the thickness, the surface smoothness, and the like may be controlled by repeating the coating.

In the case where the polyester film is used as the substrate, the film subjected to the surface treatment. Examples of the method for the surface treatment include a hydrophilization treatment method that is generally performed such as a method for laminating an acrylic resin or a sulfonic acid salt group-containing resin by coating or laminating or a method for increasing hydrophilicity of the film surface by the corona discharge treatment or the like.

(Drying)

The drying (solvent removing) step of the solvent casting method is not particularly limited, and the drying step can be performed by a generally used method such as a method for passing the film through the drying furnace via plural rollers. However, if bubbles are generated according to the evaporation of the solvent in the drying step, the characteristics of the film are remarkably decreased. Therefore, in order to prevent the decrease, it is preferable to cause the drying step to be plural steps of two or more stages and control the temperature or the air flow in the respective steps.

The residual solvent amount in the cyclic olefin-based film is generally 10 mass % or less. In this manner, it is preferable that the residual solvent is decreased, since the adhesion mark failure can be further decreased.

(Stretching)

The cyclic olefin-based film obtained as described above is preferably stretched in at least uniaxial direction of the vertical direction (MD) and the horizontal direction (TD) and more preferably stretched in biaxial direction of the vertical direction (MD) and the horizontal direction (TD). As the stretching method, the stretching method at the time of melting film forming can be employed.

After stretching, the undercoat layer can be formed in the same manner as the melting film forming.

<Transparent Conductive Film>

The cyclic olefin-based film according to the invention may be used as the conductive film. The conductive film according to the invention may have the conductive layer and the cyclic olefin-based film according to the invention, as the transparent resin film. The conductive layer may be formed into the layered shape, but preferably formed to have an intermittent portion. The intermittent portion refers to a portion to which the conductive layer is not provided, and the circumference of the intermittent portion is preferably surrounded by the conductive layer. According to the invention, forming the conductive layer so as to have the intermittent portion can be also referred to as forming the conductive layer in the pattern shape or the mesh shape. As the conductive layer, for example, conductive layers disclosed in JP2013-1009A, JP2012-216550A, JP2012-151095A, JP2012-25158A, JP2011-253546A, JP2011-197754A, JP2011-34806A, JP2010-198799A, JP2009-277466A, JP2012-216550A, JP2012-151095A, WO2010/140275A, and WO2010/114056A can be exemplified.

It is more preferable that the conductive layer used in the invention includes silver and a hydrophilic resin. Examples of the water soluble resin include gelatin, polyvinyl alcohol (PVA), polyvinylpyrrolidone (PVP), polysaccharides such as starch, cellulose and derivatives thereof, polyethylene oxide, polyvinylamine, chitosan, polylysine, a polyacrylic acid, a polyalginic acid, a polyhyaluronic acid, and carboxy cellulose. These have neutral properties, anionic properties, and cationic properties according to the ionicity of the functional group. Among these, gelatin is particularly preferable.

As the conductive layer used in the invention, a conductive layer having organic properties (for example, a conductive resin such as polythiol) or inorganic properties (for example, a semiconductor such as ITO, and metal such as gold, silver, and copper) may be used. Among these, a highly conductive inorganic layer is preferable, and metal is more preferable.

As the conductive layer using the conductive resin, conductive layers disclosed in WO12/061967A, WO2012/120949A, WO2011/105148A, WO2011/093332A, WO2010/092953A, WO2006/070801A, JP53663953B, and JP5298491B can be used.

As the conductive layer using the inorganic semiconductor, conductive layers disclosed in WO2013/175807A, WO2013/111672A, WO2013/105654A, WO2013/099736A, WO2012/074021A, JP5213694B, JP5118309B, JP4486715B, and JP4066132B can be used.

As the conductive layer using metal, conductive layers disclosed in WO2013/141275A, WO2013/099736A, WO2012/176407A, WO2011/027583A, JP5142223B, JP5112492B, JP4893587B, JP4733184B, JP3960850B, JP5129711B, JP4914309B, and JP3785086B can be used.

It is particularly preferable that the conductive layer used in the invention is formed by using a silver halide sensitive material. In a case where the silver halide sensitive material is used, the manufacturing method for the conductive layer includes three embodiments of the photosensitive material and the development treatment, as follows.

(1) An aspect of chemically or thermally developing a photosensitive silver halide black and white photosensitive material not including a physical development nuclei and forming a metallic silver portion (hereinafter, referred to as “developable silver”) on the photosensitive material above.

(2) An aspect of dissolving and physically developing a photosensitive silver halide black and white photosensitive material including physical development nuclei in a silver halide emulsion layer and forming a metallic silver portion on the photosensitive material above.

(3) An aspect of overlapping an image receiving sheet having a photosensitive silver halide black and white photosensitive material not including a physical development nuclei and a non-photosensitive layer including a physical development nuclei, performing diffusion transfer development, and forming a metallic silver portion on the non-photosensitive image receiving sheet.

Aspect (1) above is an integrated black and white developing type, and a light transmissive conductive film such as a light transmitting conductive film is formed on the photosensitive material. Since the obtained developable silver is chemically developable silver or thermally developable silver and is a filament having high specific surface area, the developable silver has high activity in the course of the plating or the physical development described below.

In Aspect (2) above, silver halide particles closely relative to the physical development nuclei are dissolved in an exposed portion are dissolved and deposited on the development nuclei, and the light transmissive conductive film such as the light transmitting conductive film is formed on the photosensitive material. This is also the integrated black and white development type. The development activity is precipitation on the physical development nuclei, and thus highly active, but the developable silver has a spherical shape having a small specific surface area.

In Aspect (3) above, a light transmissive conductive film such as the light transmitting conductive film is formed on the image receiving sheet, by dissolving and diffusing silver halide particles in the unexposed portion and depositing the silver halide particles on the development nuclei on the image receiving sheet. This is a so-called separate type, and is an aspect of separating the image receiving sheet from the photosensitive material to use.

In all aspects, all the development of a negative-type development treatment and a reversal development treatment can be selected. In the case of the diffusion transfer development type, a negative type development treatment can be performed by using an autopositive-type photosensitive material as a photosensitive material.

The chemical development, the thermal development, the dissolution and physical development, and the diffusion transfer development described herein have the same meanings as generally used in the related art and are explained in general textbooks of photographic chemical, for example, “Photographic Chemical” written by Kikuchi Shinichi (Kyoritsu Shuppan Co., Ltd., issued in 1955) and “The Theory of Photographic Processes, 4th ed.” edited by C. E. K. Mees (McMillan, issued in 1977). This specification is an invention related to the liquid treatment, but techniques of applying a thermal development method as another development method can be referred to. For example, techniques disclosed in JP2004-184693A, JP2004-334077A, JP2005-010752A, and JP2006-154700A can be applied.

The silver halide emulsion layer (layer formed by using a silver halide photosensitive material) that becomes the conductive layer according to the invention may contain additives such as a solvent or a dye, in addition to the silver halide and the binder. Examples of the silver halide include inorganic silver halide such as silver halide and organic silver halide such as silver acetate. According to the invention, it is preferable to use silver halide having excellent characteristics as an optical sensor.

The solvent used in the formation of the silver halide emulsion layer is not particularly limited, but examples thereof include water, an organic solvent (for example, alcohols such as methanol, ketones such as acetone, amides such as formamide, sulfoxides such as dimethylsulfoxide, esters such as ethyl acetate, and ethers), ionic liquid, and mixed solvents thereof.

A protective layer may be provided on the silver halide emulsion layer. The protective layer according to the invention means a layer consisting of gelatin or a binder called a high molecular polymer and is formed on the silver halide emulsion layer having photosensitivity, in order to exhibit an effect of improving scratch prevention and mechanical characteristics. The thickness thereof is preferably 0.5 μm or less. The coating method and the forming method for the protective layer forming composition are not particularly limited, but well-known coating methods and well-known forming methods can be appropriately selected. For example, with respect to the protective layer, disclosure in JP2008-250233A can be referred to.

The conductive layer may be provided on the entire surface of the cyclic olefin-based film and may be patterned on the thin wire or the like.

If the conductive layer is patterned, it is preferable since high transparency can be easily obtained, and if the conductive layer is patterned with Ag, it is particularly preferable since transparency and conductivity are excellent. Since Ag has sufficient flexibility, disconnection is hardly generated even if patterning is formed on the unevenness above, and thus Ag is more preferable.

Among Ag wiring, wiring formed of silver halide is more preferable. Since patterning is performed by exposure, thin wires can be easily formed, a gradation effect caused by the unevenness of the front surface is easily obtained, and transparency can be increased. Examples of the Ag wiring formed of silver halide include JP2012-234659A, JP2012-230665A, JP5347037B, JP2012-230664A, WO2012/098992A, JP2012-221891A, JP2012-218402A, JP2012-198879A, WO2012/121064A, JP2012-194887A, JP5345980B, JP2012-6377A, JP2012-4042A, JP2009-259479A, and JP2006-352073A.

The width of the thin wire is preferably 0.1 μm to 50 μm, more preferably 0.3 μm to 30 μm, and even more preferably 0.515 μm. If the width of the thin wire is less than 0.1 μm, the thin wire is easily broken, and if the width thereof is greater than 50 μm, the gradation effect due to the unevenness of the front surface is hardly exhibited.

According to the invention, other function layers such as an undercoat layer or an antistatic layer may be provided. As the undercoat layer, undercoat layers disclosed in paragraphs “0021” to “0023” of JP2008-250233A can be applied. As the antistatic layer, antistatic layers disclosed in paragraphs “0012”, “0014” to “0020” of JP2008-250233A can be applied.

<Touch Panel>

The cyclic olefin-based film or the conductive film according to the invention can be used in the touch panel.

The touch panel having the cyclic olefin-based film or the conductive film according to the invention is not particularly limited, and can be appropriately selected according to the purposes. Examples thereof include a front surface-type electrostatic capacitive touch panel, a projection-type electrostatic capacitive touch panel, and a resistance film-type touch panel. The touch panel includes a so-called touch sensor and a so-called touch pad. The layer configuration of an electrode portion of the touch panel sensor in the touch panel is any one of a sticking method of sticking two sheets of the transparent electrodes, a method of providing transparent electrodes on both surfaces of one sheet of the substrate, a single-sided jumper method, a through-hole method, or a single-sided laminating method. In addition, the projection type electrostatic capacitive touch panel is preferably driven by AC than by DC, and a driving method with short application time to the electrode is more preferable.

<Anti-Reflection Film>

The cyclic olefin-based film according to the invention can be used as the support of the anti-reflection film. In a case of an image display with high resolution and high quality such as a liquid crystal display (LCD), in addition to the dust resistance described above, it is preferable to use a transparent anti-reflection film having antistatic performance for preventing contrast decrease due to the reflection of the external light on the displaying surface and the reflected glare of the image.

<Optical Film>

The cyclic olefin-based film according to the invention may be used as the optical film. Specific examples thereof include an optical film obtained by using the cyclic olefin-based film as a support and forming an optically anisotropic layer and a hardcoat layer on the support and an optical film as a protective film of a polarizing film.

As the optically anisotropic layer or the hardcoat layer, well-known optically anisotropic layers or hardcoat layers can be used. Examples thereof include optically anisotropic layers or hardcoat layers disclosed in JP2012-215704A and JP2013-231955A.

<Base Film for Printed Electronics>

Printed electronics is to form an electronic circuit or the like by using a printing technique, and the cyclic olefin-based film according to the invention can be used as a base film for printed electronics.

For example, the electronic circuit can be formed, for example, by using the printing technique disclosed in JP2010-87146A.

<Barrier Film>

The cyclic olefin-based film according to the invention may be used as the barrier film. Specific examples thereof include a barrier film obtained by using the cyclic olefin-based film as the support and having a barrier layer on the support.

As the barrier layer, it is possible to use a well-known barrier layer, and examples thereof include barrier layers disclosed in JP2013-202972A.

<Polarization Plate>

The cyclic olefin-based film or the optical film according to the invention can be used in the polarization plate. The polarization plate according to the invention has a polarizer and protective films provided on both surfaces of the polarizer above, and the cyclic olefin-based film or the optical film according to the invention can be used as at least one side of the protective film above. It is preferable that the cyclic olefin-based film or the optical film has a contact angle of water to the front surface of the transparent support on the opposite side of the side that has a light scattering layer or an anti-reflection layer, that is, the front surface on the side bonded to the polarizer in the range of 10° to 50°. For example, a pressure sensitive adhesive layer is provided on one surface of the cyclic olefin-based film or the optical film according to the invention and can be arranged on the outermost front surface of the display.

<Display>

The cyclic olefin-based film, the optical film, or the polarization plate according to the invention can be used in various displays such as a liquid crystal display (LCD), a plasma display panel (PDP), an electroluminescent display (ELD), and a cathode tube display (CRT). The cyclic olefin-based film, the optical film, or the polarization plate according to the invention is preferably arranged on the visible side of the display surface of the image display.

<<Liquid Crystal Display>>

The cyclic olefin-based film, the optical film, or the polarization plate according to the invention is particularly preferably used on the outermost layer of the display such as the liquid crystal display. The liquid crystal display has a liquid crystal cell and two sheets of polarization plates arranged on both surfaces of the liquid crystal cell, and the liquid crystal cell contains the liquid crystal between two sheets of the electrode substrates. One sheet of optically anisotropic layers is arranged between the liquid crystal cell and one of the polarization plates, or two sheets of optically anisotropic layers are arranged between the liquid crystal cell and both of the polarization plates.

The liquid crystal cell is preferably in a TN mode, a VA mode, an OCB mode, an IPS mode, or an ECB mode.

In the liquid crystal cell in the TN mode, a rod-shaped liquid crystalline molecule is substantially horizontally aligned when the voltage is not applied and is further twisted and aligned to 60° to 120°.

The liquid crystal cell of the TN mode is most widely used as a color TFT liquid crystal display and is disclosed in various documents.

In the liquid crystal cell in the VA mode, the rod-shaped liquid crystalline molecule when the voltage is not applied is substantially vertically aligned.

The liquid crystal cell in the VA mode includes (1) the liquid crystal cell in the VA mode in a narrow sense (disclosed in JP1990-176625A (JP-H02-176625A)) obtained by substantially vertically aligning the rod-shaped liquid crystalline molecule when the voltage is not applied and substantially horizontally aligning the rod-shaped liquid crystalline molecule when the voltage is applied, (2) the liquid crystal cell (in the MVA mode) in which the VA mode is changed to a multi domain for viewing angle expansion (disclosed in SID97, Digest of Tech. Papers (preliminary draft) 28 (1997) 845), and (3) the liquid crystal cell (disclosed in preliminary draft 58 to 59 (1998) of Japanese Liquid Crystal Conference) in a mode (n-ASM mode) of substantially vertically aligning the rod-shaped liquid crystalline molecule when the voltage is not applied and twisting the rod-shaped liquid crystalline molecule to the multi domain alignment when the voltage is applied, and (4) the liquid crystal cell in a survival mode (issued in LCD International 98).

The liquid crystal cell in the OCB mode is a liquid crystal cell in a band alignment mode of aligning the rod-shaped liquid crystalline molecule in the substantially reverse direction (symmetrically) on the upper portion and the lower portion of the liquid crystal cell and is disclosed in U.S. Pat. No. 4,583,825A and U.S. Pat. No. 5,410,422A. Since the rod-shaped liquid crystalline molecule is symmetrically aligned on the upper portion and the lower portion of the liquid crystal cell, the liquid crystal cell in the band alignment mode has a self-compensatory function. Therefore, the liquid crystal mode is called an optically compensatory bend (OCB) liquid crystal mode. The liquid crystal display in the band alignment mode has an advantage of having fast response speed.

The liquid crystal cell in the IPS mode is a method of performing switching by applying a horizontal field effect to nematic liquid crystal, and specifically disclosed in pages 577 to 580 and pages 707 to 710 of Proc. IDRC (Asia Display '95).

In the liquid crystal cell in the ECB mode, the rod-shaped liquid crystalline molecule is substantially horizontally aligned when the voltage is not applied. The ECB mode is one of the liquid crystal displaying mode having the simplest structure, and details thereof are disclosed, for example, in JP1993-203946A (JP-H05-203946A).

<<Plasma Display Panel (PDP)>>

The plasma display panel (PDP) is generally formed of gas, a glass substrate, an electrode, an electrode lead material, and a thick film printing material, and a fluorescent body. The glass substrate is formed of two sheets of a front surface glass substrate and a rear surface glass substrate. An electrode and an insulating layer are formed on the two sheets of glass substrates. A fluorescent body layer is further formed on the rear surface glass substrate. Two glass substrates are assembled, and gas is sealed therebetween.

The plasma display panel (PDP) can be obtained by using a plasma display panel which is commercially available. The plasma display panel is disclosed in JP1993-205643A (JP-H05-205643A) and JP1997-306366A (JP-H09-306366A).

A front surface plate may be arranged on the front surface of the plasma display panel. It is preferable that the front surface plate includes sufficient strength for protecting a plasma display panel. The front surface plate may have a gap with the plasma display panel to be used or may be directly bonded to the main body of the plasma display.

In the image display such as the plasma display panel, an optical filter may be directly bonded to the front surface of the display. In a case where the front surface plate is provided before the display, the optical filter can be attached to the front side (outer side) or the rear side (display side) of the front surface plate.

<<Organic EL Element>>

The cyclic olefin-based film according to the invention may be used as a substrate (substrate film) or a protective film of an organic EL element or the like. In a case where the film according to the invention is used in the organic EL element or the like, contents of JP1999-335661A (JP-H11-335661A), JP1999-335368A (JP-H11-335368A), JP2001-192651A, JP2001-192652A, JP2001-192653A, JP2001-335776A, JP2001-247859A, JP2001-181616A, JP2001-181617A, JP2002-181816A, JP2002-181617A, and JP2002-056976A can be applied. It is preferable to use contents of JP2001-148291A, JP2001-221916A, and JP2001-231443A together.

### EXAMPLES

Hereinafter, the characteristics of the invention are described in greater detail with reference to examples and comparative examples. Materials, amounts used, ratios, treatment details, treatment orders, and the like that are represented in the examples below can be appropriately changed without departing from the gist of the invention. Accordingly, the scope of the invention is not construed in a limited manner by specific examples represented below.

### Example 1

### Preparing of Coating Liquid for Forming Undercoat Layer

Components as below were mixed so as to prepare the coating liquid.

| | |
|---|---|
| Urethane-based binder | 3.90 parts by mass |
| (TAKELAC WS5100, manufactured by | |
| Mitsui Chemicals, Inc., | |
| Concentration of 30 mass %) | |
| Oxazoline group-containing aqueous | 0.32 parts by mass |
| dispersible polymer (EPOCROS K-2010E | |
| (acryl polymer having oxazoline group and | |
| polyalkylene oxide chain), Tg = −50° C., | |
| manufactured by Nippon Shokubai Co., Ltd., | |
| Solid content: 40 mass %) | |
| Colloidal silica | 0.27 parts by mass |
| (SNOWTEX UP, manufactured by | |
| Nissan Chemical Industries, Ltd., | |
| Solid content: 10 mass % water diluted) | |
| Slipping agent: Carnauba wax | 1.67 parts by mass |
| (SELOSOL 524, manufactured by | |
| Chukyo Yushi Co., Ltd., | |
| Solid content: 3 mass % water diluted) | |
| Surfactant A: Surfactant | 1.67 parts by mass |
| (NAROACTY CL95, manufactured by | |
| Sanyo Chemical Industries, Ltd., | |
| Solid content: 1 mass % aqueous solution) | |
| Surfactant B: Surfactant | 2.67 parts by mass |
| (RAPISOL A-90, manufactured by | |
| NOF Corporation, | |
| Solid content: 1 mass % aqueous solution) | |
| Distilled water | 89.50 parts by mass |

<Laminating of Undercoat Layer>

A corona discharge treatment was performed on one surface of ARTON D4540 (manufactured by JSR Corporation, film thickness of 40 μm) which was a cyclic olefin-based film used as a substrate in the condition of 8 kJ/m². Subsequently, the surface on the side subjected to the corona discharge treatment of the substrate was coated with the mixed coating liquid for undercoat layer, such that the film thickness after drying was 90 nm, and drying is performed for one minute at the film surface temperature of 90° C., so as to obtain a cyclic olefin-based film in which the undercoat layer is formed.

<Laminating of Antihalation (AH) Layer and Emulsion Layer (Conductive Layer)>

(Antihalation (AH) Layer)

A coating liquid for forming an antihalation (AH) layer including 84 g of an solid dispersed dye A with respect to 100 g of gelatin is prepared.

Solid Dispersed Dye a

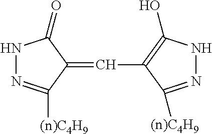

(Silver Halide Photosensitive Material)

Emulsion for forming a conductive layer (silver halide photosensitive material) including 10.0 g of gelatin with respect to Ag of 150 g in a water medium and containing silver iodobromochloride particles (I=0.2 mol %, Br=40 mol %) having an equivalent spherical diameter average of 0.1 μm was prepared. In this emulsion, K₃Rh₂Br₉ and K₂IrCl₆ were added such that the concentration thereof became 10⁻⁷ (mol/mol Ag), and Rh ions and Ir ions were doped to silver bromide particles. Na₂PdCl₄ was added to this emulsion, gold sulfur sensitization was further performed by using gold chloride and sodium thiosulfate.

(Conductive Layer Attached Film)

Simultaneous multilayer coating was performed by using the coating liquid for forming the antihalation (AH) layer and the emulsion (silver halide photosensitive material) together with the a gelatin film hardening agent on the cyclic olefin-based film in which the produced undercoat layer was formed, so as to form a cyclic olefin layer, an undercoat layer, a AH layer, and an emulsion layer, in this order. At this point, a coating amount (coating silver) of silver in the emulsion layer was 7 g/m² in terms of silver, the film thickness of the AH layer was 1 μm, and the volume ratio of Ag/gelatin in the emulsion layer was 2/1. Coating of 20 m was performed in the width of 25 cm on the cyclic olefin-based film in the width of 30 cm, and both ends of the cyclic olefin-based film are cut down by 3 cm, respectively, such that the central portion of the coating of 24 cm was remained, so as to obtain the cyclic olefin-based film (conductive layer attached film) in which the roll-shaped emulsion layer (conductive layer) was formed.

The obtained conductive layer attached film was set to be the film of Example 1.

### Examples 2 and 3

In Example 1, films of Examples 2 and 3 were obtained in the same manner as in Example 1, except for changing EPOCROS K-2010E respectively to EPOCROS K-2020E (Tg=0° C., manufactured by Nippon Shokubai Co., Ltd.) or EPOCROS K-2030E (Tg=50° C., manufactured by Nippon Shokubai Co., Ltd.).

### Example 4

In Example 1, a film of Example 4 was obtained in the same manner as in Example 1, except for changing the binder from a urethane-based binder WS5100 to an olefin-based binder SE1010 and changing the used oxazoline group-containing polymer from EPOCROS K-2010E to an oxazoline-containing water soluble polymer WS-700, and mixing the binder and the used oxazoline group-containing polymer with components below.

| | |
|---|---|
| Olefin-based binder | 5.73 parts by mass |
| (AROBASE SE1010, manufactured by | |
| Unitika, Ltd., | |
| Concentration of 20 mass %) | |
| Oxazoline group-containing water | 0.51 parts by mass |
| soluble polymer (EPOCROS WS-700, | |
| Tg = 50° C., manufactured by | |
| Nippon Shokubai Co., Ltd., | |
| Solid content: 25 mass %) | |
| Solloidal silica | 0.26 parts by mass |
| (SNOWTEX UP, manufactured by | |
| Nissan Chemical Industries, Ltd., | |
| Solid content: 10 mass % water diluted) | |
| Slipping agent: Carnauba wax | 1.63 parts by mass |
| (SELOSOL 524, manufactured by | |
| Chukyo Yushi Co., Ltd., | |
| Solid content: 3 mass % water diluted) | |
| Surfactant A: Surfactant | 1.63 parts by mass |
| (NAROACTY CL95, manufactured by | |
| Sanyo Chemical Industries, Ltd., | |
| Solid content: 1 mass % aqueous solution) | |
| Surfactant B: Surfactant | 2.61 parts by mass |
| (RAPISOL A-90, manufactured by | |
| NOF Corporation, | |
| Solid content: 1 mass % aqueous solution) | |
| Distilled water | 87.62 parts by mass |

### Example 5

In Example 4, the film of Example 5 was obtained in the same manner as in Example 4, except for changing the binder from the olefin-based binder SE1010 to an acrylic binder AS-563A (manufactured by Daicel Finechem Ltd., Concentration: 40 mass %) and mixing the binder with components below.

| | |
|---|---|
| Acrylic binder | 2.95 parts by mass |
| (AS-563A, manufactured by | |
| Daicel Finechem Ltd., | |
| Concentration: 40 mass %) | |
| Oxazoline group-containing water | 0.52 parts by mass |
| soluble polymer (EPOCROS WS-700, | |
| Tg = 50° C., manufactured by | |
| Nippon Shokubai Co., Ltd., | |
| Solid content: 25 mass %) | |
| Colloidal silica | 0.27 parts by mass |
| (SNOWTEX UP, manufactured by | |
| Nissan Chemical Industries, Ltd., | |
| Solid content: 10 mass % water diluted) | |
| Slipping agent: carnauba wax | 1.68 parts by mass |
| (SELOSOL 524, manufactured by | |
| Chukyo Yushi Co., Ltd., | |
| Solid content: 3 mass % water diluted) | |
| Surfactant A: Surfactant | 1.68 parts by mass |
| (NAROACTY CL95, manufactured by | |
| Sanyo Chemical Industries, Ltd., | |
| Solid content: 1 mass % aqueous solution) | |
| Surfactant B: Surfactant | 2.69 parts by mass |
| (RAPISOL A-90, manufactured by | |
| NOF Corporation, | |
| Solid content: 1 mass % aqueous solution) | |
| Distilled water | 90.20 parts by mass |

### Example 6

In Example 4, the film of Example 6 was obtained in the same manner as in Example 4 except for changing the binder from the olefin-based binder SE1010 to a silicone-based binder CERANATE WSA1070 (manufactured by DIC Corporation, Concentration: 40 mass %) and mixing the binder with components below.

| | |
|---|---|
| Silicone-based binder | 2.95 parts by mass |
| (CERANATE WSA1070, DIC Corporation, | |
| Concentration: 40 mass %) | |
| Oxazoline group-containing water | 0.52 parts by mass |
| soluble polymer (EPOCROS WS-700, | |
| Tg = 50° C., manufactured by | |
| Nippon Shokubai Co., Ltd., | |
| Solid content: 25 mass %) | |
| Colloidal silica | 0.27 parts by mass |
| (SNOWTEX UP, manufactured by | |
| Nissan Chemical Industries, Ltd., | |
| Solid content: 10 mass % water diluted) | |
| Slipping agent: Carnauba wax | 1.68 parts by mass |
| (SELOSOL 524, manufactured by | |
| Chukyo Yushi Co., Ltd., | |
| Solid content: 3 mass % water diluted) | |
| Surfactant A: Surfactant | 1.68 parts by mass |
| (NAROACTY CL95, manufactured by | |
| Sanyo Chemical Industries, Ltd., | |
| Solid content: 1 mass % aqueous solution) | |
| Surfactant B: Surfactant | 2.69 parts by mass |
| (RAPISOL A-90, manufactured by | |
| NOF Corporation, | |
| Solid content: 1 mass % aqueous solution) | |
| Distilled water | 90.20 parts by mass |

### Example 7

In Example 4, the film of Example 7 was obtained in the same manner as in Example 4 except for changing the binder from the olefin-based binder SE1010 to the polyester-based binder VYLONAL MD1245 (manufactured by Toyobo Co., Ltd., concentration of 34 mass %) and mixing the binder with components below.

| | |
|---|---|
| Polyester-based binder | 3.45 parts by mass |
| (VYLONAL MD1245, manufactured | |
| by Toyobo Co., Ltd., | |
| concentration of 34 mass %) | |
| Oxazoline group-containing water | 0.52 parts by mass |
| soluble polymer (EPOCROS WS-700, | |
| Tg = 50° C., manufactured by | |
| Nippon Shokubai Co., Ltd., | |
| Solid content: 25 mass %) | |
| Colloidal silica | 0.27 parts by mass |
| (SNOWTEX UP, manufactured by | |
| Nissan Chemical Industries, Ltd., | |
| Solid content: 10 mass % water diluted) | |
| Slipping agent: Carnauba wax | 1.67 parts by mass |
| (SELOSOL 524, manufactured by | |
| Chukyo Yushi Co., Ltd., | |
| Solid content: 3 mass % water diluted) | |
| Surfactant A: Surfactant | 1.67 parts by mass |
| (NAROACTY CL95, manufactured by | |
| Sanyo Chemical Industries, Ltd., | |
| Solid content: 1 mass % aqueous solution) | |
| Surfactant B: Surfactant | 2.68 parts by mass |
| (RAPISOL A-90, manufactured by | |
| NOF Corporation, | |
| Solid content: 1 mass % aqueous solution) | |
| Distilled water | 89.74 parts by mass |

### Example 8

In Example 4, the film of Example 8 was obtained in the same manner as in Example 4, except for changing the binder from the olefin-based binder SE1010 to the styrene-butadiene-based binder NIPOL LX415 (manufactured by ZEON Corporation, concentration of 43 mass %) and mixing the binder with components below.

| | |
|---|---|
| Styrene-butadiene-based binder | 2.75 parts by mass |
| (NIPOL LX415, manufactured by | |
| ZEON Corporation, | |
| concentration of 43 mass %) | |
| Oxazoline group-containing water | 0.53 parts by mass |
| soluble polymer (EPOCROS WS-700, | |
| Tg = 50° C., manufactured by | |
| Nippon Shokubai Co., Ltd., | |
| Solid content: 25 mass %) | |
| Colloidal silica | 0.27 parts by mass |
| (SNOWTEX UP, manufactured by | |
| Nissan Chemical Industries, Ltd., | |
| Solid content: 10 mass % water diluted) | |
| Slipping agent: Carnauba wax | 1.69 parts by mass |
| (SELOSOL 524, manufactured by | |
| Chukyo Yushi Co., Ltd., | |
| Solid content: 3 mass % water diluted) | |
| Surfactant A: Surfactant | 1.69 parts by mass |
| (NAROACTY CL95, manufactured by | |
| Sanyo Chemical Industries, Ltd., | |
| Solid content: 1 mass % aqueous solution) | |
| Surfactant B: Surfactant | 2.70 parts by mass |
| (RAPISOL A-90, manufactured by | |
| NOF Corporation, | |
| Solid content: 1 mass % aqueous solution) | |
| Distilled water | 90.39 parts by mass |

### Example 9

In Example 4, the film of Example 9 was obtained in the same manner as in Example 4, except for changing the binder from the olefin-based binder SE1010 to the urethane-based binder TAKELAC WS5100 (manufactured by Mitsui Chemicals, Inc., concentration of 30 mass %) and mixing the binder with components below.

| | |
|---|---|
| Urethane-based binder | 3.89 parts by mass |
| (TAKELAC WS5100, manufactured by | |
| Mitsui Chemicals, Inc., | |
| concentration of 30 mass %) | |
| Oxazoline group-containing water | 0.52 parts by mass |
| soluble polymer (EPOCROS WS-700, | |
| Tg = 50° C., manufactured by | |
| Nippon Shokubai Co., Ltd., | |
| Solid content: 25 mass %) | |
| Colloidal silica | 0.27 parts by mass |
| (SNOWTEX UP, manufactured by | |
| Nissan Chemical Industries, Ltd., | |
| Solid content: 10 mass % water diluted) | |
| Slipping agent: Carnauba wax | 1.67 parts by mass |
| (SELOSOL 524, manufactured by | |
| Chukyo Yushi Co., Ltd., | |
| Solid content: 3 mass % water diluted) | |
| Surfactant A: Surfactant | 1.67 parts by mass |
| (NAROACTY CL95, manufactured by | |
| Sanyo Chemical Industries, Ltd., | |
| Solid content: 1 mass % aqueous solution) | |
| Surfactant B: Surfactant | 2.66 parts by mass |
| (RAPISOL A-90, manufactured by | |
| NOF Corporation, | |
| Solid content: 1 mass % aqueous solution) | |
| Distilled water | 89.32 parts by mass |

### Examples 10 to 14

In Example 9, the films of Examples 10 to 14 were respectively obtained in the same manner as in Example 9, except for changing the contents of the binders and the oxazoline group-containing polymers used to contents presented in Table 1 below.

### Examples 15 to 20

In Example 12, films of Examples 15 to 20 were respectively obtained in the same manner as in Example 12 except for performing coating with the composition for forming the undercoat layer such that the film thickness after drying became the film thicknesses presented in Table 1. In Example 20, rolling wrinkles were generated when the film was wounded as a film roll after the undercoat layer coating.

### Example 21

In Example 9, the film of Example 15 was obtained in the same manner as in Example 9, except for changing the oxazoline group-containing polymer from EPOCROS WS700 to EPOCROS WS300 (Tg=90° C.) and mixing the binder with components below.

| | |
|---|---|
| Urethane-based binder | 3.86 parts by mass |
| (TAKELAC WS5100, manufactured by | |
| Mitsui Chemicals, Inc., | |
| concentration of 30 mass %) | |
| Oxazoline group-containing water | 1.29 parts by mass |
| soluble polymer (EPOCROS WS-300, | |
| Tg = 90° C., manufactured by | |
| Nippon Shokubai Co., Ltd., | |
| Solid content: 10 mass %) | |
| Colloidal silica | 0.27 parts by mass |
| (SNOWTEX UP, manufactured by | |
| Nissan Chemical Industries, Ltd., | |
| Solid content: 10 mass % water diluted) | |
| Slipping agent: Carnauba wax | 1.65 parts by mass |
| (SELOSOL 524, manufactured by | |
| Chukyo Yushi Co., Ltd., | |
| Solid content: 3 mass % water diluted) | |
| Surfactant A: Surfactant | 1.65 parts by mass |
| (NAROACTY CL95, manufactured by | |
| Sanyo Chemical Industries, Ltd., | |
| Solid content: 1 mass % aqueous solution) | |
| Surfactant B: Surfactant | 2.64 parts by mass |
| (RAPISOL A-90, manufactured by | |
| NOF Corporation, | |
| Solid content: 1 mass % aqueous solution) | |
| Distilled water | 88.63 parts by mass |

### Comparative Examples 1 to 2

In Example 9, films of Comparative Examples 1 to 3 in the same manner as in Example 9, except for changing the content of the oxazoline group-containing polymer to contents presented in Table 2 below.

### Comparative Example 3

The film of Comparative Example 3 was obtained in the same manner as in Comparative Example 2, except for changing the thickness of the undercoat layer to the thickness presented in Table 2.

### Comparative Examples 4 to 9

In Examples 4 to 9, the films of Comparative Examples 4 to 9 were obtained in the same manner as in Examples 4 to 9, except for changing the oxazoline group-containing polymer from EPOCROS WS-700 to aqueous carbodiimide CARBODILITE V-02-L2 (manufactured by Nisshinbo Chemical Inc., water diluted in concentration of 40 mass % to 25 mass %).

### Comparative Example 10

In Example 9, the film of Comparative Example 10 was obtained in the same manner in Example 9, except for changing the oxazoline group-containing polymer from EPOCROS WS-700 to the epoxy-containing water soluble polymer MODEPICS 302 (manufactured by Arakawa Chemical Industries, Ltd., concentration of 33 mass % to 25 mass % water diluted).

### Comparative Example 11

In Example 9, the film of Comparative Example 11 was obtained in the same manner as in Example 9, except for changing the oxazoline group-containing polymer from EPOCROS WS-700 to the isocyanate-containing water soluble polymer ERASTRON E-37 (manufactured by DKS Co., Ltd., concentration of 25 mass %).

### Comparative Example 12

The film of Comparative Example 12 was obtained in the same manner as in Example 9 except for not using the oxazoline group-containing polymer (crosslinking agent).

### Comparative Example 13

In Example 9, the film of Comparative Example 13 was obtained in the same manner as in Example 9, except for changing the oxazoline group-containing polymer from EPOCROS WS-700 to the oxazoline-containing water soluble low molecular compound (low molecular water soluble oxazolinemonomer VOZO, 2-vinyl-2-oxazoline, manufactured by Kohjin Film & Chemicals, Co., Ltd., concentration of 25 mass % water diluted). The molecular weight of the low molecular water soluble oxazolinemonomer VOZO was 97.

[Evaluation]

Dry adhesiveness and wet adhesiveness of the respective films of Examples 1 to 21 and Comparative Examples 1 to 13 were evaluated as below.

(Dry Adhesiveness)

The films of respective examples and respective comparative examples which were the produced conductive layer attached films were cut in the size of 12 cm×3 cm so as to produce samples. After the produced samples were maintained for one hour at 23° C. in the condition of the relative humidity of 50%, polyimide tapes (No. 541, manufactured by Sumitomo 3M Limited) were bonded to the emulsion layer, and subsequently the polyimide tapes were peeled such that peeling angles were 180°. Dry adhesiveness was evaluated based on five ranks below, by calculating an area in which the peeling was generated in the film. A film in Rank 3 or greater was determined to be in a practically preferable level. A film in Rank 4 or greater was more preferable, and a film in Rank 5 was particularly preferable.

The peeling of the films of the respective examples and the respective comparative examples was mainly peeling between the undercoat layer and the antihalation layer.

5: Peeling was not generated at all.

4: With respect to an area to which a polyimide tape was bonded, a peeled area was less than 30%.

3: With respect to an area to which a polyimide tape was bonded, a peeled area was 30% or greater and less than 60%.

2: With respect to an area to which a polyimide tape was bonded, a peeled area was 60% or greater and less than 90%.

1: With respect to an area to which a polyimide tape was bonded, a peeled area was 90% or greater.

(Wet Adhesiveness (Wet Scratch))

The films of the respective examples and the respective comparative examples which were the produced conductive layer attached films were maintained for 32 hours in an oven at 50° C. Thereafter, the films were cut into a size of 12 cm×3 cm, were immersed in distilled water at 24° C. for 2 minutes, and immediately thereafter, while the films were not dried, scratch tests were performed. In the scratch test, a length of 10 cm was scratched under conditions of sapphire needles of 1.0 mmφ and a load of 200 g by using a continuous weighted scratch strength tester (HEIDON-18 type, manufactured by Shinto Scientific Co., Ltd.), and it was checked whether peeling was generated or not. The case where peeled length was 10 cm was set to be a load of 0 g, and the case where peeling was not generated at all was set to be a load of 200 g, so as to calculate the load when the peeling was generated, from the length in which peeling was generated. It was considered that the load of 60 g or greater was in the practicable level. It was preferable that the load was 95 g or greater and it was more preferable that the load was 150 g or greater.

The peeling generated in the films in the respective examples and the respective comparative examples was mainly peeling between the substrate and the undercoat layer or peeling between the undercoat layer and the antihalation layer.

TABLE 1

| | Undercoat layer | | | | | | Evaluation | |
|---|---|---|---|---|---|---|---|---|
| | Oxazoline group-containing polymer | | | Binder | | Thick- | Dry | Wet |
| | | Content | Tg | | Content | ness | adhe- | adhesiveness |
| | Type | (mass %) | (° C.) | Type | (mass %) | (nm) | siveness | (g) |
| Example 1 | EPOCROS K-2010E | 10 | −50 | Urethane | 90 | 90 | 3 | 60 |
| Example 2 | EPOCROS K-2020E | 10 | 0 | Urethane | 90 | 90 | 3 | 60 |
| Example 3 | EPOCROS K-2030E | 10 | 50 | Urethane | 90 | 90 | 3 | 90 |
| Example 4 | WS-700 | 10 | 50 | Olefin | 90 | 90 | 3 | 100 |
| Example 5 | WS-700 | 10 | 50 | Acryl | 90 | 90 | 4 | 120 |
| Example 6 | WS-700 | 10 | 50 | Silicone | 90 | 90 | 3 | 110 |
| Example 7 | WS-700 | 10 | 50 | Ester | 90 | 90 | 4 | 90 |
| Example 8 | WS-700 | 10 | 50 | SBR | 90 | 90 | 4 | 120 |
| Example 9 | WS-700 | 10 | 50 | Urethane | 90 | 90 | 5 | 110 |
| Example 10 | WS-700 | 2 | 50 | Urethane | 98 | 90 | 4 | 90 |
| Example 11 | WS-700 | 3 | 50 | Urethane | 97 | 90 | 5 | 110 |
| Example 12 | WS-700 | 8 | 50 | Urethane | 92 | 90 | 5 | 140 |
| Example 13 | WS-700 | 12 | 50 | Urethane | 88 | 90 | 5 | 110 |
| Example 14 | WS-700 | 15 | 50 | Urethane | 85 | 90 | 4 | 90 |
| Example 15 | WS-700 | 8 | 50 | Urethane | 92 | 20 | 3 | 60 |
| Example 16 | WS-700 | 8 | 50 | Urethane | 92 | 30 | 4 | 100 |

TABLE 2

| | Undercoat layer | | | | | | Evaluation | |
|---|---|---|---|---|---|---|---|---|
| | Oxazoline group-containing polymer | | | Binder | | Thick- | Dry | Wet |
| | | Content | Tg | | Content | ness | adhe- | adhesiveness |
| | Type | (mass %) | (° C.) | Type | (mass %) | (nm) | siveness | (g) |
| Example 17 | WS-700 | 8 | 50 | Urethane | 92 | 60 | 5 | 120 |
| Example 18 | WS-700 | 8 | 50 | Urethane | 92 | 110 | 5 | 90 |
| Example 19 | WS-700 | 8 | 50 | Urethane | 92 | 400 | 4 | 80 |
| Example 20 | WS-700 | 8 | 50 | Urethane | 92 | 500 | 3 | 60 |
| Example 21 | EPOCROS WS-300 | 10 | 90 | Urethane | 90 | 90 | 5 | 150 |
| Comparative | EPOCROS K-2030E | 1 | 50 | Urethane | 99 | 90 | 2 | 40 |
| Example 1 | | | | | | | | |
| Comparative | EPOCROS K-2030E | 16 | 50 | Urethane | 84 | 90 | 2 | 50 |
| Example 2 | | | | | | | | |
| Comparative | EPOCROS K-2030E | 16 | 50 | Urethane | 84 | 500 | 2 | 20 |
| Example 3 | | | | | | | | |
| Comparative | Aqueous carbodiimide | 10 | — | Olefin | 90 | 90 | 1 | 20 |
| Example 4 | CARBODILITE | | | | | | | |
| Comparative | Aqueous carbodiimide | 10 | — | Acryl | 90 | 90 | 1 | 40 |
| Example 5 | CARBODILITE | | | | | | | |
| Comparative | Aqueous carbodiimide | 10 | — | Silicone | 90 | 90 | 1 | 60 |
| Example 6 | CARBODILITE | | | | | | | |
| Comparative | Aqueous carbodiimide | 10 | — | Ester | 90 | 90 | 2 | 30 |
| Example 7 | CARBODILITE | | | | | | | |
| Comparative | Aqueous carbodiimide | 10 | — | SBR | 90 | 90 | 2 | 50 |
| Example 8 | CARBODILITE | | | | | | | |
| Comparative | Aqueous carbodiimide | 10 | — | Urethane | 90 | 90 | 2 | 60 |
| Example 9 | CARBODILITE | | | | | | | |
| Comparative | Epoxy-containing water | 10 | — | Urethane | 90 | 90 | 2 | 60 |
| Example 10 | soluble polymer | | | | | | | |
| Comparative | Isocyanate-containing | 10 | — | Urethane | 90 | 90 | 2 | 50 |
| Example 11 | water soluble polymer | | | | | | | |
| Comparative | — | 0 | — | Urethane | 100 | 90 | 2 | 40 |
| Example 12 | | | | | | | | |
| Comparative | Oxazoline group- | 10 | — | Urethane | 90 | 90 | 1 | 40 |
| Example 13 | containing water soluble | | | | | | | |
| | low molecular polymer | | | | | | | |

In this table, SBR represents styrene butadiene-based binder

From Tables 1 and 2, in Examples 1 to 21 in which the undercoat layer includes an oxazoline group-containing polymer, it has been understood that both of dry adhesiveness and wet adhesiveness were excellent. Meanwhile, it has been found that, in Comparative Examples 4 to 13 in which the oxazoline group-containing polymer is not included in the undercoat layer, dry adhesiveness is inferior to the examples, and further in some comparative examples, wet adhesiveness is inferior to the example.

### INDUSTRIAL APPLICABILITY

According to the invention, a cyclic olefin-based film having excellent dry adhesiveness and excellent wet adhesiveness can be obtained. The cyclic olefin-based film according to the invention is suitably used in an optical film, a conductive film, a base film for printed electronics, a barrier film, a touch panel, a polarization plate, and a display, and industrial applicability thereof is high.

What is claimed is:

1. A cyclic olefin-based film comprising:
an undercoat layer on at least one surface of a layer consisting of a cyclic olefin-based resin,
wherein a content of an oxazoline group-containing polymer included in the undercoat layer is 2 mass % to 15 mass %.

2. The cyclic olefin-based film according to claim 1,
wherein a thickness of the undercoat layer is 20 nm to 400 nm.

3. The cyclic olefin-based film according to claim 1,
wherein the oxazoline group-containing polymer is a water soluble oxazoline group-containing polymer.

4. The cyclic olefin-based film according to claim 1,
wherein a content of the oxazoline group-containing polymer in the undercoat layer is 3 mass % to 12 mass %.

5. The cyclic olefin-based film according to claim 1,
wherein the oxazoline group-containing polymer is an acryl polymer having an oxazoline group and a polyalkylene oxide chain.

6. The cyclic olefin-based film according to claim 1,
wherein a glass transition temperature of the oxazoline group-containing polymer is 50° C. or greater.

7. The cyclic olefin-based film according to claim 1,
wherein the undercoat layer includes at least one resin selected from a polyolefin resin, an acryl resin, a modified silicone resin, a polyester resin, a polyurethane resin, and a styrene butadiene rubber resin.

8. The cyclic olefin-based film according to claim 4,
wherein the undercoat layer includes at least one resin selected from a polyolefin resin, an acryl resin, a modified silicone resin, a polyester resin, a polyurethane resin, and a styrene butadiene rubber resin.

9. A method for manufacturing the cyclic olefin-based film according to claim 1, comprising:
forming an undercoat layer by coating at least one surface of a layer consisting of a cyclic olefin-based resin with a coating liquid at least including an oxazoline group-containing polymer and a resin and then curing the coating liquid.

10. An optical film comprising:
the cyclic olefin-based film according to claim 1.

11. A conductive film comprising:
the cyclic olefin-based film according to claim 1; and
a conductive layer.

12. Abase film for printed electronics comprising:
the cyclic olefin-based film according to claim 1.

13. A barrier film comprising:
the cyclic olefin-based film according to claim 1.

14. A touch panel comprising:
the cyclic olefin-based film according to claim 1.

15. A touch panel comprising:
the conductive film according to claim 11.

16. A polarization plate comprising:
the cyclic olefin-based film according to claim 1.

17. A polarization plate comprising:
the optical film according to claim 10.

18. A display comprising:
the cyclic olefin-based film according to claim 1.

19. A display comprising:
the optical film according to claim 10.

20. A display comprising:
the polarization plate according to claim 16.
